(19) United States
(12) Patent Application Publication
(10) Pub. No.: US 2018/0226617 A1
(43) Pub. Date: Aug. 9, 2018

(54) DISPLAY DEVICE

(71) Applicant: Japan Display Inc., Tokyo (JP)

(72) Inventor: Takuya NAKAGAWA, Tokyo (JP)

(21) Appl. No.: 15/878,544

(22) Filed: Jan. 24, 2018

(30) Foreign Application Priority Data
Feb. 3, 2017 (JP) 2017-018525

(51) Int. Cl. H01L 51/56; G09G 3/3233; H01L 51/52; H01L 51/00

(52) U.S. Cl. CPC H01L 51/56; G09G 3/3233; H01L 51/5256; H01L 27/3246; G09G 2300/0426; G09G 2320/045; G09G 2320/0626; H01L 51/0097

(57) ABSTRACT

A display device includes a substrate, a circuit layer arranged on a first surface of the substrate and including a transistor, wiring and an insulating layer, and a plurality of pixels arranged over the circuit layer, wherein a display region where the plurality of pixels is located and a periphery region surrounding the display region are located above the first surface of the substrate, the circuit layer is located across the display region and the periphery region, and a through hole passing through the circuit layer is located in the periphery region of the circuit layer.

### CROSS REFERENCE TO RELATED APPLICATIONS

This application is based upon and claims the benefit of priority from the prior Japanese Patent Application No. 2017-018525, filed on Feb. 3 2017, the entire contents of which are incorporated herein by reference.

### FIELD

One embodiment of the present invention is related to a display device. For example, the present invention is related to a structure of circuit layer in a display device.

### BACKGROUND

In an organic electroluminescence (hereinafter, referred to as an “organic EL”) display device, a light emitting element is arranged in each pixel, and an image is displayed by independently controlling the light emitted by the pixels. A light emitting element has a structure in which a layer (hereinafter, referred to as a “light emitting layer”) is sandwiched between a pair of electrodes, where one electrode as an anode is distinguished from the other electrode as a cathode. When electrons are injected from the cathode and holes are injected from the anode, the electrons and holes recombine in the light emitting layer. In this way, light emitting molecules within the light emitting layer are excited by a surplus of discharged energy and light is emitted by subsequent de-excitation.

The organic EL display device, the anode in each light emitting element is arranged in each pixel (also called a pixel electrode), and the cathode is arranged as a common electrode applied with a common potential across a plurality of pixels. The organic EL display device controls the light emitted by a pixel by controlling the potential of a pixel electrode for each pixel with respect o the potential of the common electrode.

The light emitting layer of the organic EL display device deteriorates easily when moisture enters, and there is a problem that a non-lighting region called a dark spot occurs. In order to solve such a problem, many organic EL display devices are arranged with a sealing layer for preventing the entrance of moisture.

However, in the manufacturing process, when separating a plurality of organic EL display devices arranged on a mother glass, there is a problem whereby the display device is damaged.

In order to deal with such a problem, for example, Japanese Laid Open Patent Publication No. 2015-195106 discloses a manufacturing method of an organic EL display device in which a resin film is formed on a substrate, an organic EL layer including a plurality of organic EL elements is formed on the resin film, a plurality of first groove parts each surrounding the organic EL element in a multiple manner on a surface of the resin film, cutting the substrate at a position overlapping any one first groove part excluding a first grove part among the plurality of first groove parts having the smallest distance from the organic EL element, and peeling the substrate from the resin film.

However, when the substrate is cut and peeled from the resin film, there is a fear that the sealing film which seals the organic EL element or the like may be damaged.

### SUMMARY

A display device according to one embodiment of the present invention includes a substrate, a circuit layer arranged on a first surface of the substrate and including a transistor, wiring and an insulating layer, and a plurality of pixels arranged over the circuit layer, wherein a display region where the plurality of pixels is located and a periphery region surrounding the display region are located above the first surface of the substrate, the circuit layer is located across the display region and the periphery region, and a through hole passing through the circuit layer is located in the periphery region of the circuit layer.

### BRIEF DESCRIPTION OF DRAWINGS

FIG. 1A is a top view diagram for explaining the structure of a display device related to one embodiment of the present invention;

FIG. 1B is a cross-sectional diagram for explaining the structure of a display device related to one embodiment of the present invention;

FIG. 1C is a cross-sectional diagram for explaining the structure of a display device related to one embodiment of the present invention;

FIG. 2A is a top view diagram for explaining a manufacturing method of a display device related to one embodiment of the present invention;

FIG. 2B is a cross-sectional diagram for explaining a manufacturing method of a display device related to one embodiment of the present invention;

FIG. 2C is a cross-sectional diagram for explaining a manufacturing method of a display device related to one embodiment of the present invention;

FIG. 3A is a top view diagram for explaining a manufacturing method of a display device related to one embodiment of the present invention;

FIG. 3B is a cross-sectional diagram for explaining a manufacturing method of a display device related to one embodiment of the present invention;

FIG. 3C is a cross-sectional diagram for explaining a manufacturing method of a display device related to one embodiment of the present invention;

FIG. 4A is a top view diagram for explaining a manufacturing method of a display device related to one embodiment of the present invention;

FIG. 4B is a cross-sectional diagram for explaining a manufacturing method of a display device related to one embodiment of the present invention;

FIG. 4C is a cross-sectional diagram for explaining a manufacturing method of a display device related to one embodiment of the present invention;

FIG. 5A is a top view diagram for explaining a manufacturing method of a display device related to one embodiment of the present invention;

FIG. 5B is a cross-sectional diagram for explaining a manufacturing method of a display device related to one embodiment of the present invention;

FIG. 5C is a cross-sectional diagram for explaining a manufacturing method of a display device related to one embodiment of the present invention;

FIG. 6A is a top view diagram for explaining a manufacturing method of a display device related to one embodiment of the present invention;

FIG. 6B is a cross-sectional diagram for explaining a manufacturing method of a display device related to one embodiment of the present invention;

FIG. 6C is a cross-sectional diagram for explaining a manufacturing method of a display device related to one embodiment of the present invention;

FIG. 7A is a top view diagram for explaining a manufacturing method of a display device related to one embodiment of the present invention;

FIG. 7B is a cross-sectional diagram for explaining a manufacturing method of a display device related to one embodiment of the present invention;

FIG. 7C is a cross-sectional diagram for explaining a manufacturing method of a display device related to one embodiment of the present invention;

FIG. 8A is a top view diagram for explaining a manufacturing method of a display device related to one embodiment of the present invention;

FIG. 8B is a cross-sectional diagram for explaining a manufacturing method of a display device related to one embodiment of the present invention;

FIG. 8C is a cross-sectional diagram for explaining a manufacturing method of a display device related to one embodiment of the present invention;

FIG. 9 is a top view diagram for explaining a manufacturing method of a display device related to one embodiment of the present invention;

FIG. 10 is a cross-sectional diagram for explaining a manufacturing method of a display device related to one embodiment of the present invention;

FIG. 11 is a cross-sectional diagram for explaining a manufacturing method of a display device related to one embodiment of the present invention; and

FIG. 12 is a cross-sectional diagram for explaining a manufacturing method of a display device related to one embodiment of the present invention.

### DESCRIPTION OF EMBODIMENTS

A display device according to the embodiments of the present invention is explained in detail below while referring to the drawings. Furthermore, the display device of the present invention is not limited to the following embodiments and the invention can be carried out by making various modifications. In all of the embodiments, the same parts are explained denoted with the same reference numerals. In addition, for the convenience of explanation, the dimensional ratios in the drawings may be different from actual ratios or a part of the structure may be omitted from the drawings.

### First Embodiment

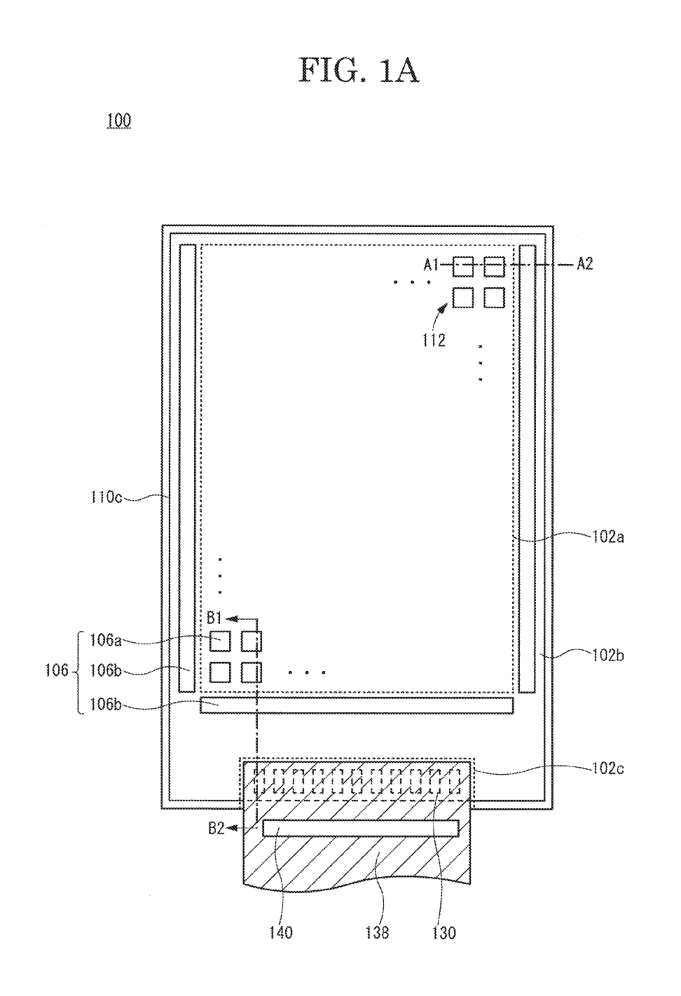

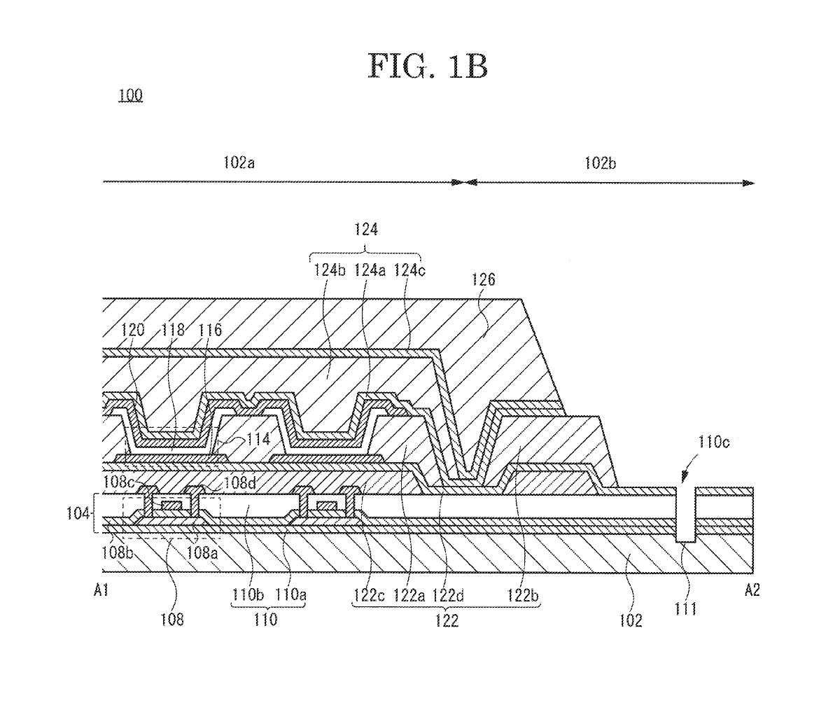

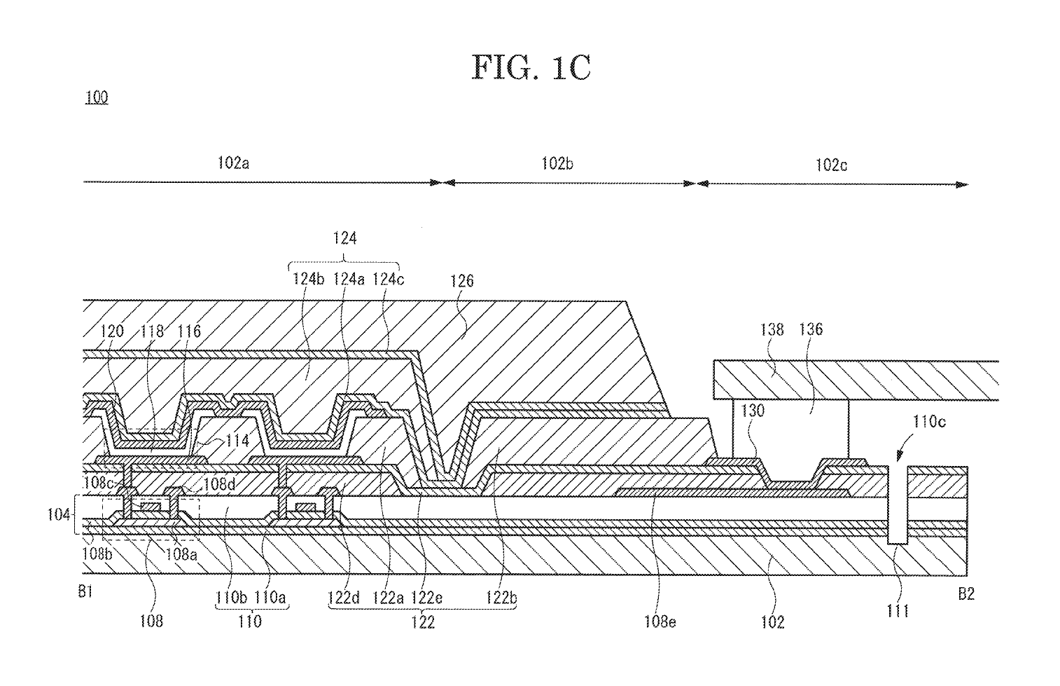

FIG. 1A is a top view diagram showing a structure of a display device 100 according to the present embodiment. The display device 100 has a display region 102a, a periphery region 102b and a terminal region 102c.

The display region 102a is a region for displaying an image. A plurality of pixels 112 are arranged in the display region 102a. The plurality of pixels 112 is arranged in a matrix in two directions intersecting each other. In the present embodiment, the plurality of pixels 112 is arranged in a matrix in two directions orthogonal to each other. Each of the plurality of pixels 112 is arranged with a pixel circuit 106a for controlling light emission of a pixel.

The periphery region 102b is a region which is adjacent to the periphery of the display region 102a and surrounds the display region 102a. A periphery circuit 106b for controlling the light emission of the plurality of pixels 112 may be arranged in the periphery region 102b. As the periphery circuit 106b, a scanning line drive circuit which selects a pixel row to write video data to from among the plurality of pixels 112, a video line drive circuit which supplies a voltage corresponding to the video signal to each of the plurality of pixels 112 may be included. Although described in detail later, a through hole 110c arranged provided in a circuit layer 104 in the display device 100 and arranged in a frame shape surrounding a circuit 106 is shown in FIG. 1A.

The terminal region 102c is a region for connecting the display device 100 and a flexible printed circuit substrate (FPC substrate) 138 and the like. The terminal region 102c may be arranged along one side of the display device 100 and a plurality of connection terminals 130 (also referred to simply as terminals) is arranged. The flexible printed circuit substrate (FPC substrate) 138 may be arranged with a driver IC 140.

FIG. 1B and FIG. 1C are cross-sectional diagrams showing the structure of the display device 100 according to the present embodiment and each shows a structure of a cross-section along the lines A1-A2 and B1-B2 shown in FIG. 1A. The display device 100 includes a substrate 102, a circuit layer 104, the plurality of pixels 112, a partition layer 122, a sealing layer 124, a protective layer 126 and a plurality of connection terminals 130.

The substrate 102 supports a circuit layer 104 and the plurality of pixels 112 arranged on first surface side thereof. Furthermore, although described in detail later in the manufacturing method of the display device 100, the substrate 102 may have a bottomed hole 111 (recess part) on this first surface. The bottomed hole 111 is arranged in a region that overlaps the through hole 110c of the circuit layer 104.

Glass, quartz, plastic, metal, ceramic, or the like can be used as the material of the substrate 102. In the case when flexibility is provided to the display device 100, a base material may be formed on the substrate 102. In this case, the substrate 102 is also called a support substrate. The substrate is an insulating layer having flexibility. For example, a material selected from polymer materials exemplified by polyimide, polyamide, polyester and polycarbonate can be used as a specific material of the base material.

The circuit layer 104 is arranged on first surface of the substrate 102 and has the circuit 106 and an insulating layer 110. The circuit 106 controls light emitted by the plurality of pixels 112. The circuit 106 includes the pixel circuit 106a, the periphery circuit 106b and various other wirings. The pixel circuit 106a is arranged for each of the plurality of pixels 112 arranged in the display region 102a and controls light emitted by each of the plurality of pixels 112. The periphery circuit 106b is arranged in the periphery region 102b and controls the pixel circuit 106a. The scanning line drive circuit which selects a pixel row to write video signal to among the plurality of pixels 112 arranged in a matrix, and the video line drive circuit which supplies a voltage corresponding to the video signal is supplied to each of the plurality of pixels 112 may be included as the periphery circuit 106b.

As is shown in FIG. 1B and FIG. 1C, the circuit layer 104 includes a transistor 108. The transistor 108 includes a semiconductor layer 108a, a gate insulating layer 108b, a gate electrode 108c, and a source/drain electrode 108d and the like. The semiconductor layer 108a is arranged in an island shape above a first inorganic insulating layer 110a. The first inorganic insulating layer 110a is formed from an inorganic insulating film such as a silicon nitride film, a silicon oxide film, a silicon nitride oxide film or a silicon oxynitride film. For example, a Group 14 element such as silicon or an oxide semiconductor or the like can be used as a material of the semiconductor layer 108a. A compound containing a Group 13 element such as indium or gallium can be used as the oxide semiconductor, for example, a mixed oxide of indium and gallium (IGO) can be used. A Group 12 element may be further contained in the oxide semiconductor, for example, a mixed oxide (IGZO) containing indium, gallium, and zinc can be used. There is no limitation to the crystallinity of the semiconductor layer 108a and it may have any of a single crystal, polycrystal, microcrystalline or amorphous state.

The gate insulating layer 108b is arranged above the semiconductor layer 108a. The gate insulating layer 108b is arranged above a plurality of transistors 108. However, the gate insulating layer 108b may also be arranged at least in a region overlapping the gate electrode 108c. A material that can be used for the first inorganic insulating layer 110a can be used as a material for the gate insulating layer 108b, and a single layer structure or a stacked structure selected from these materials may be used.

The gate electrode 108c overlaps the semiconductor layer 108a interposed by the gate insulating layer 108b. In the semiconductor layer 108a, a region overlapping the gate electrode 108c is a channel region. A metal such as titanium, aluminum, copper, molybdenum, tungsten, tantalum or an alloy thereof or the like can be used as a material of the gate electrode 108c. The gate electrode 108c can be formed having a single layer of any of these materials or a stacked structure of a plurality of materials selected from these materials. For example, it is possible to adopt a structure having a relatively high melting point such as titanium, tungsten, molybdenum or the like and sandwiching a highly conductive metal such as aluminum or copper.

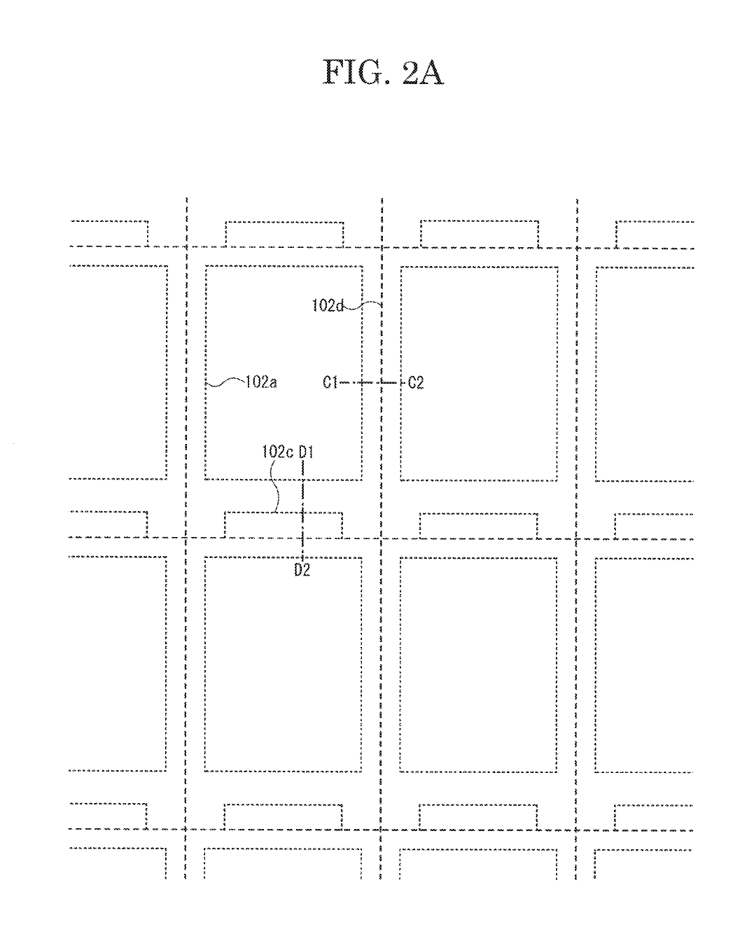

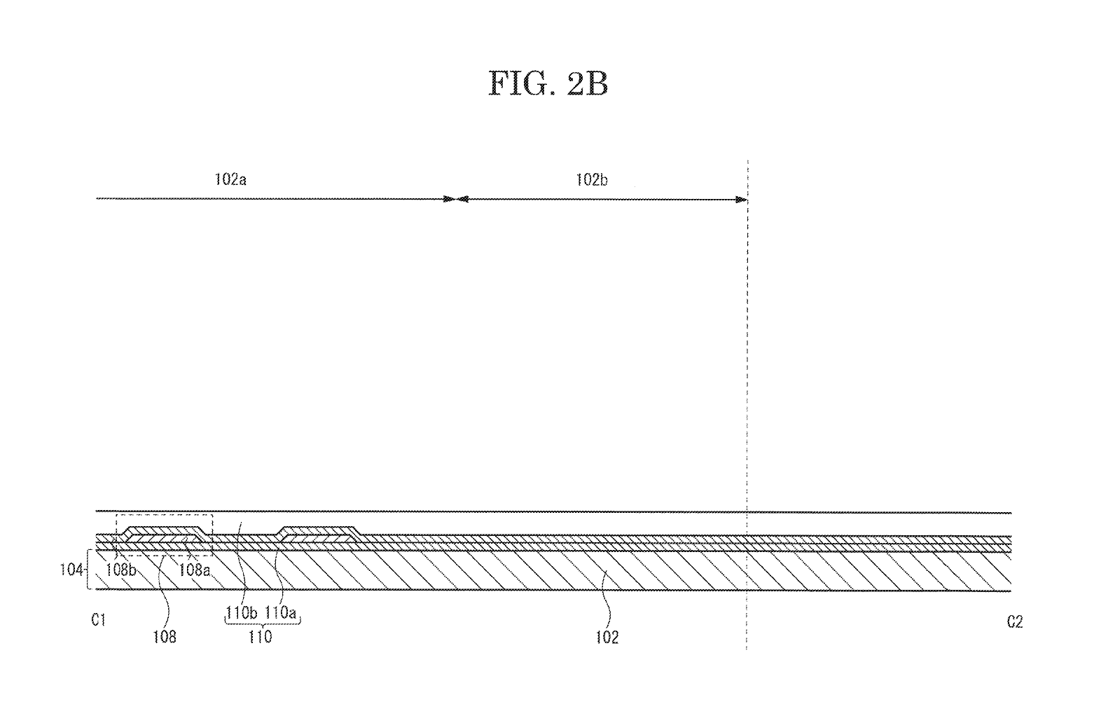

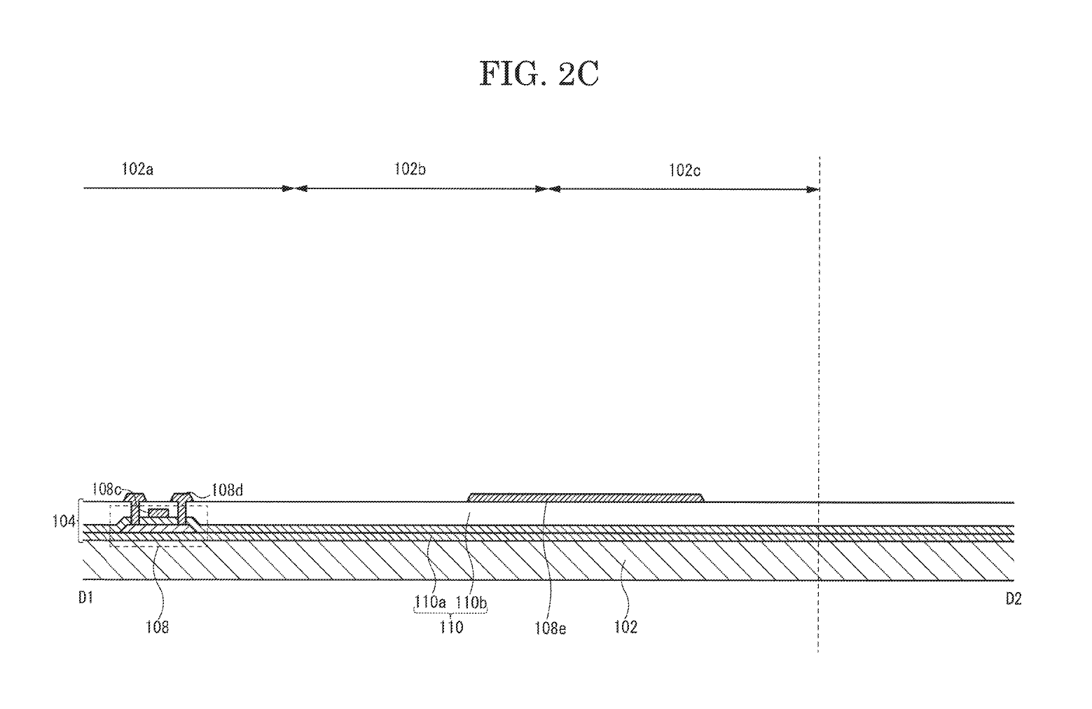

The source/drain electrode 108d is arranged above the insulating layer 110b and is electrically connected to the source/drain region of the semiconductor layer 108a in an opening arranged in the insulating layer 110b and the gate insulating layer 108b. A terminal wiring 108e is further arranged above the insulating layer 110b. That is, as is shown in FIG. 2C, it is possible for the terminal wiring 108e to exist in the same layer as the source/drain electrode 108d. In addition, the present invention is not limited to this structure and the terminal wiring 108e may also be arranged in the same layer as the gate electrode 108c (not shown in the diagram).

Although a top gate type transistor is exemplified in FIG. 1B and FIG. 1C as an example of the transistor 108, the structure of the transistor 108 is not limited and a bottom gate type transistor, a multi-gate type transistor having a plurality of gate electrodes 108c, or a dual gate type transistor having a structure in which the upper and lower sides of the gate electrode 108a are sandwiched by two gate electrodes 108c. In addition, although an example in which one transistor 108 is arranged for each of the plurality of pixels 112 is shown in FIG. 1B and FIG. 1C, each of the plurality of pixels 112 may further include a plurality of transistors 108 or a semiconductor element such as and a capacitor element.

As is shown in FIG. 1A, in the insulating layer 110, a through hole 110c is arranged in the periphery of the circuit 106 and the plurality of pixels 112 in a planar view. In the present embodiment, the through hole 110c has a frame shape surrounding the circuit 106 and the plurality of pixels 112. The circuit 106 and the outer side of the frame shaped through hole 110c surrounding the plurality of pixels 112 are regions where only the circuit 106 but only the insulating layer 110. Here, the circuit 106 includes a pixel circuit 106a, a periphery circuit 106b and various other wirings. Various wirings include a connection wiring for connecting the pixel circuit 106a and the periphery circuit 106b and the plurality of connection terminals 130.

By adopting such a structure, it is possible to prevent defects from growing further inward from the through hole 110c in the vicinity of an end part of the display device 100, for example, when a defect such as a crack exists in the insulating layer 110.

This defect easily occurs when dividing a plurality of display devices 100 formed on a mother substrate, for example, in the manufacturing process of the display device 100. Furthermore, particularly in a flexible display device, there is concern that cracks grow due to a defect by the repetition of bending. When the crack grows and reaches the display region 102a for example, a problem arises in that it causes a defect to occur in the transistor 108. In addition, the generated cracks become entry paths for moisture and moisture reaching the display region 102a from the exterior becomes a cause of degradation of the light emitting layer 118.

In the present embodiment, by arranging the through hole 110c as described above, it is possible to prevent the transistor 108 from breaking and a light emitting element 114 from being deteriorated by moisture. In this way, it is possible to improve manufacturing yield and reliability of the display device 100.

The insulating layer 110 includes the first inorganic insulating layer 110a and a second inorganic insulating layer 110b. The first inorganic insulating layer 110a has an arbitrary structure and is arranged under the transistor 108. The first inorganic insulating layer 110a is a layer for preventing impurities such as alkali metal from diffusing from the substrate 102 (or the base material) into the transistor 108 and the like. An inorganic insulating material is used as the material of the first inorganic insulating layer 110a. Silicon nitride, silicon oxide, silicon nitride oxide, silicon oxynitride, or the like can be used as the inorganic insulating material. In the case when the impurity concentration in the first inorganic insulating layer 110a is small, the first inorganic insulating layer 110a may be omitted or may be arranged to cover only a part of the substrate 102.

The second inorganic insulating layer 110b is arranged above the transistor 108. A material which can be used for the first inorganic insulating layer 110a can be used as a material of the second inorganic insulating layer 110b, and either a single layer structure or a stacked layer structure can be used.

Each of the plurality of pixels 112 has the light emitting element 114. The light emitting element 114 has a layer structure in which a first electrode 116, a light emitting layer 118 and a second electrode 120 are stacked from the substrate 102 side. Carriers are injected into the light emitting layer 118 from the first electrode 116 and the second electrode 120, and carrier recombination occurs in the light emitting layer 118. In this way, the light emitting molecules in the light emitting layer 118 are in an excited state, and light emission is obtained through a process of relaxation to a ground state.

The first electrode 116 is arranged above a planarization insulating layer 122c. The first electrode 116 covers openings formed in the planarization insulating layer 122c and the inorganic insulating layer 122d and is arranged to be electrically connected to the source/drain electrode 108d. In this way, a current is supplied to the light emitting element 114 via the transistor 108. In the case when the light emitted from the light emitting element 114 is extracted from the second electrode 120, a material that can reflect visible light is selected as the material of the first electrode 116. In this case, a metal having high reflectivity such as silver or aluminum or an alloy thereof is used for the first electrode 116. Alternatively, a conductive oxide layer having translucency is arranged above the layer containing these metals or alloys. Examples of the conductive oxide include ITO and IZO. Conversely, in the case when light emitted from the light emitting element 114 is extracted from the first electrode 116, ITO or IZO is used as the material for the first electrode 116.

The light emitting layer 118 is arranged to cover the first electrode 116 and the first partition wall 122a. The structure of the light emitting layer 118 can be appropriately selected and it can be formed by combining, for example, a carrier injection layer, a carrier transport layer, a light emitting layer 118, a carrier blocking layer and an exciton blocking layer and the like. The light emitting layer 118 can be formed to include different materials for each pixel 112. By appropriately selecting the material used for the light emitting layer 118, it is possible to obtain different light emitting colors for each pixel 112. Alternatively, the structure of the light emitting layer 118 may be the same among the pixels 112. In such a structure, since the same light emitting color is output from the light emitting layer 118 of each pixel 112, for example, the light emitting layer 118 can be formed to emit white light and various colors (for example, red, green and blue) may be extracted from each pixel 112 respectively by using a color filter.

The second electrode 120 is arranged above the light emitting layer 118. The second electrode 120 may also be arranged in common to the plurality of pixels 112. In the case when the light emitted from the light emitting element 114 is extracted from the second electrode 120, the material of the second electrode 120 is selected from a conductive oxide having translucency such as ITO. Alternatively, the second electrode 120 can be formed with a thickness such that visible light can pass through the metal described above. In this case, a conductive oxide having translucency may be further stacked.

The partition wall layer 122 is arranged above the first surface of the substrate 102. The partition wall layer 122 has a first partition wall 122a, a second partition wall 122b, a planarization insulating layer 122c and an inorganic insulating layer 122d.

The first partition wall 122a is arranged between adjacent pixels 112 among the plurality of pixels 112 in a planar view and surrounds each of the plurality of pixels 112. The first partition wall 122a covers a periphery edge of the surface of the first electrode 116 on the light emitting layer 118 side. By covering the periphery of the first electrode 116, the first partition wall 122a can prevent disconnection of the light emitting layer 118 and the second electrode 120 arranged above. In a planar view, the region where the first electrode 116 and the light emitting layer 118 are in contact is a light emitting region.

The second partition wall 122b has an interval from the first partition wall 122a in a planar view and has a frame shape surrounding the first partition wall 122a. In other words, a frame groove part is arranged between the second partition wall 122b and the first partition wall 122a. That is, the second partition wall 122b is separated from the first partition wall 122a in a planar view. As is explained in detail later, when forming the first organic insulating layer 124b which forms the sealing layer 124 in the manufacturing process, it is necessary to selectively form the first organic insulating layer 124b in a region within the surface of the substrate 102 so that the first organic insulating layer 124b covers the display region 102a and spreads over the edge of the substrate 102. When the first organic insulating layer 124b expands to the end part of the substrate 102, there is concern that moisture may enter the display device 100 from the end part via the first organic insulating layer 124b. The first organic insulating layer 124b is selectively applied to the display region 102a, for example, by an inkjet method. At this time, the second partition wall 122b has a function of blocking the first organic insulating layer 124b so as not to spread outside of the second partition wall 122b.

For example, an organic insulating material such as an epoxy resin, an acrylic resin, or the like can be used as the material of the first partition wall 122a and the second partition wall 122b.

The planarization insulating layer 122c is arranged on the upper layer side of the circuit layer 104 and on the lower layer side of the light emitting element 114. The planarization insulating layer 122c absorbs irregularities caused by the transistor 108 and provides a flat surface. A material that can be used for the first partition wall 122a and the second partition wall 122b can be used as the material of the planarization insulating layer 122c.

The inorganic insulating layer 122d has an arbitrary structure and has a function of protecting the transistor 108. Furthermore, a capacitor is formed by the first electrode 116 of the light emitting element 114 and an electrode (not shown in the diagram) arranged under the inorganic insulating layer 122d so as to sandwich the first electrode 116 and the inorganic insulating layer 122d.

The planarization insulating layer 122c and the inorganic insulating layer 122d are arranged with a plurality of openings. One of these is arranged for electrically connecting the first electrode 116 of the light emitting element 114 and the source/drain electrode 108d of the transistor 108. The other is arranged to expose a part of the terminal wiring 108e. The terminal wiring 108e exposed by this opening is connected to the FPC substrate 138 by an anisotropic conductive film 136 for example.

A sealing layer 124 is arranged above the plurality of pixels 112 and the partition wall layer 122. In the present embodiment, the through hole 110c of the circuit layer 104 further passes through the sealing layer 124. The sealing layer 124 includes a third inorganic insulating layer 124a, a first organic insulating layer 124b and a fourth inorganic insulating layer 124c.

The third inorganic insulating layer 124a covers an irregular (convex-concave) surface caused by the partition wall layer 122. The third inorganic insulating layer 124a covers the bottom surface of a groove part 122e between the first partition wall 122a and the second partition wall 122b and the partition wall. In the present embodiment, an end part of the third inorganic insulating layer 124a is arranged on the outer side of the through hole 110c in a planar view.

The third inorganic insulating layer 124a has at least the following two functions. One function is to be arranged above the third inorganic insulating layer 124a and arranged so that the first organic insulating layer 124b which is likely to allow moisture to pass through, does not come into contact with the light emitting element 114. In this way, moisture contained in the first organic insulating layer 124b or moisture entering the first organic insulating layer 124b from the outside of the display device 100 is prevented from reaching the light emitting layer 118 and deteriorating the light emitting layer 118. The other function is that it is arranged so as not to generate a moisture entrance path through the organic material between the first partition wall 122a and the second partition wall 122b. This prevents moisture contained in the second partition wall 122b or moisture entering the second partition wall 122b from the outside of the display device 100 from entering the second partition wall 122b and deteriorating the light emitting layer 118.

Due to the above description, it is preferred to use an insulating material having low moisture permeability for the material of the third inorganic insulating layer 124a. It is preferable to use an inorganic insulating material as an insulating material having low moisture permeability. For example, silicon oxide, silicon nitride, silicon oxynitride, silicon nitride oxide, aluminum oxide, aluminum nitride, aluminum oxynitride and aluminum nitride oxide or the like can be used as the inorganic insulating layer. In addition, a structure in which a plurality of materials selected from these are stacked may also be used.

The first organic insulating layer 124b is arranged above the third inorganic insulating layer 124a. The end part of the first organic insulating layer 124b is arranged inside the through hole 110c in a planar view and between the first partition wall 122a and the second partition wall 122b. The first organic insulating layer 124b is arranged to planarize unevenness due to the first partition wall 122a.

If such unevenness is not sufficiently planarized and the fourth inorganic insulating layer 124c is arranged above the first organic insulating layer 124b, the fourth inorganic insulating layer 124c cannot sufficiently cover any remaining unevenness in the first organic insulating layer 124b, defects such as cracks occur in the fourth inorganic insulating layer 124c, and a moisture entry path due to this defect may be produced.

The fourth inorganic insulating layer 124c is arranged above the first organic insulating layer 124b. In the present embodiment, an end part of the fourth inorganic insulating layer 124c in a planar view is arranged on the outer side of the through hole 110c and along the end part of the third inorganic insulating layer 124a. In other words, the first organic insulating layer 124b is sealed by the third inorganic insulating layer 124a and the fourth inorganic insulating layer 124c. By adopting such a structure, it is possible to block a moisture entrance path from the exterior of the display device 100 to the interior via the first organic insulating layer 124b. It is preferred to use an insulating material having low moisture permeability as the material of the fourth inorganic insulating layer 124c, and a material similar to the material of the third inorganic insulating layer 124a can be used.

Furthermore, it is not absolutely necessary that the end part of the fourth inorganic insulating layer 124c be arranged along the end part of the third inorganic insulating layer 124a. The sealing layer 124 may be formed so that the first organic insulating layer 124b is sealed by the third inorganic insulating layer 124a and the fourth inorganic insulating layer 124c.

A protective layer 126 is arranged on an upper layer of the sealing layer 124. That is, the protective layer 126 is arranged on an upper layer of the fourth inorganic insulating layer 124c. The end part of the protective layer 126 is arranged above the second partition wall 122b. In the present embodiment, the protective layer 126 is arranged along the end part of the third inorganic insulating layer 124a. The same material as the material that can be used for the first organic insulating layer 124b described above can be used as the material of the protective layer 126.

The plurality of connection terminals 130 is arranged above the first surface of the substrate 102. Each of the plurality of connection terminals 130 is electrically connected to connection wiring through an opening formed in the inorganic insulating layer 122d and the planarization insulating layer 122c. The plurality of connection terminals 130 is also arranged on the outer side of the protection layer 126 in a planar view.

According to the present embodiment, it is possible to prevent the circuit 106 from breaking due to defects such as cracks being occuring in the vicinity of the end part of the display device 100, and the light emitting element 114 from deteriorating due to moisture. In this way, it is possible to provide the display device 100 with improved manufacturing yield and reliability.

Next, a manufacturing method of the display device 100 according to the present embodiment is explained in detail. FIG. 2A to FIG. 8A are top view diagrams showing a manufacturing method of the display device 100 according to the present embodiment. FIG. 2B to FIG. 8B are cross-sectional views showing a manufacturing method of the display device 100 according to the present embodiment and show cross sections along the line C1-C2 in the top view. FIG. 2C to FIG. 8C are cross-sectional views showing a manufacturing method of the display device 100 according to the present embodiment and show cross sections along the line D1-D2 in the top view.

The substrate 102 supports various elements such as a circuit layer 104 and the plurality of pixels 112 arranged on first surface side of the substrate 102. Therefore, a member having heat resistance to the temperature of processes of various elements formed above the substrate and chemical stability to chemicals used in the process is used for the substrate 102. Glass, quartz, plastic, metal, ceramic and the like are used as the material of the substrate 102.

In the case when flexibility is provided to the display device 100, a base material may be formed on the substrate 102. In this case, the substrate 102 is also called a support substrate. The substrate is an insulating layer which has flexibility. For example, a material selected from polymer materials exemplified by polyimide, polyamide, polyester and polycarbonate can be included as a specific material of the base material. The substrate can be formed by applying a wet film forming method such as a printing method, an inkjet method, a spin coating method, a dip coating method and a lamination method and the like.

Next, a method of forming the circuit layer 104 on first surface of the substrate 102 is explained while referring to FIG. 2A, FIG. 2B, and FIG. 2C. A plurality of regions for dividing into a plurality of display devices 100 in a later manufacturing process are defined on the surface of substrate 102. A dividing line 102d is shown in FIG. 2A and the substrate 102 is divided along the dividing line 102d in a later manufacturing process. The circuit layer 104 is arranged in each of a plurality of regions on the surface of the substrate and includes a circuit for controlling light emitted by the plurality of pixels 112 and an insulating layer 110 which covers the circuit.

As is shown in FIG. 2B, a first inorganic insulating layer 110a is formed above the substrate 102. An inorganic insulating material can be used as the material of the first inorganic insulating layer 110a. Silicon nitride, silicon oxide, silicon nitride oxide or silicon oxynitride can be used as the inorganic insulating material. The first inorganic insulating layer 110a can be formed having a single layer structure or a stacked layer structure by applying a chemical vapor deposition (CVD) method or a sputtering method and the like. Furthermore, the first inorganic insulating layer 110a has an arbitrary structure and it is not always necessary for it to be arranged.

Next, a semiconductor layer 108a is formed. The semiconductor layer 108a is formed using a Group 14 element such as silicon as described previously. Alternatively, the semiconductor layer 108a may be formed using an oxide semiconductor. For example, the semiconductor layer 108a may be fabricated using a silicon film formed by a CVD method using silane gas or the like as a raw material. The amorphous silicon obtained in this way may be crystallized by a heat treatment or irradiated with light such as a laser. In the case where the semiconductor layer 108a is formed using an oxide semiconductor, it is possible to form the semiconductor layer 108a by a sputtering method or the like.

Next, a gate insulating layer 108b is formed to cover the semiconductor layer 108a. The gate insulating layer 108b may have a single layer structure or a stacked layer structure and can be formed using the same method as the first inorganic insulating layer 110a.

Next, a gate electrode 108c is formed above the gate insulating layer 108b. A metal such as titanium, aluminum, copper, molybdenum, tungsten, tantalum or an alloy thereof can be used for the gate electrode 108c. The gate electrode 108c can be formed with a single layer of a film formed by any one of these materials or a stacked layer structure of a plurality of films each formed of a different material. For example, it is possible to adopt a structure in which a metal with high conductivity such as aluminum or copper is sandwiched between metals having a relatively high melting point such as titanium, tungsten or molybdenum. The gate electrode 108c can be formed by a sputtering method or a CVD method.

Next, a second inorganic insulating layer 110b is formed above the gate electrode 108c. A material which can be used for the first inorganic insulating layer 110a can be used as the material of the second inorganic insulating layer 110b. The second inorganic insulating layer 110b may have a single layer structure or a stacked layer structure selected from these materials. The second inorganic insulating layer 110b can be formed using the same method as the first inorganic insulating layer 110a.

Next, etching is performed on the second inorganic insulating layer 110b and the gate insulating layer 108b to form an opening which reaches the semiconductor layer 108a. The opening can be formed by performing plasma etching in a gas which includes a fluorine-containing hydrocarbon for example.

As is shown in FIG. 2C, a metal layer is formed to cover an opening and etching is carried out to form the source/drain electrode 108d. In the present embodiment, the terminal wiring 108e is formed simultaneously with the source/drain electrode 108d. Therefore, it is possible for the source/drain electrode 108 and the terminal wiring 108e to be present in the same layer. The metal layer can have a structure similar to the structure of the gate electrode 108c and can be formed using the same method as the formation method of the gate electrode 108c.

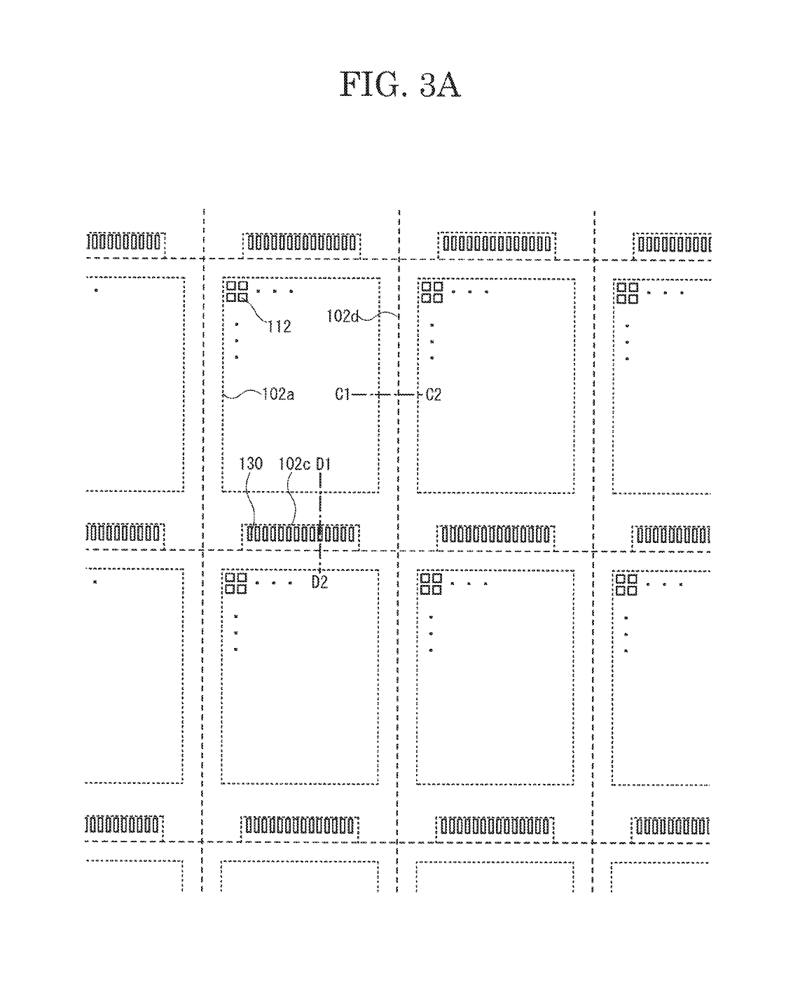

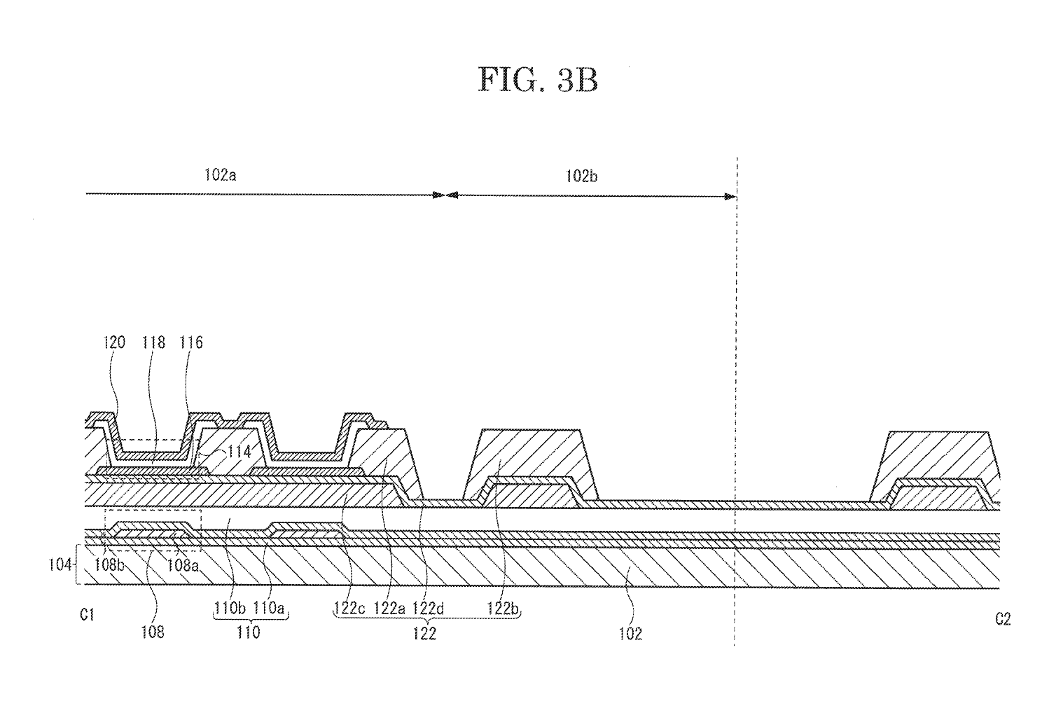

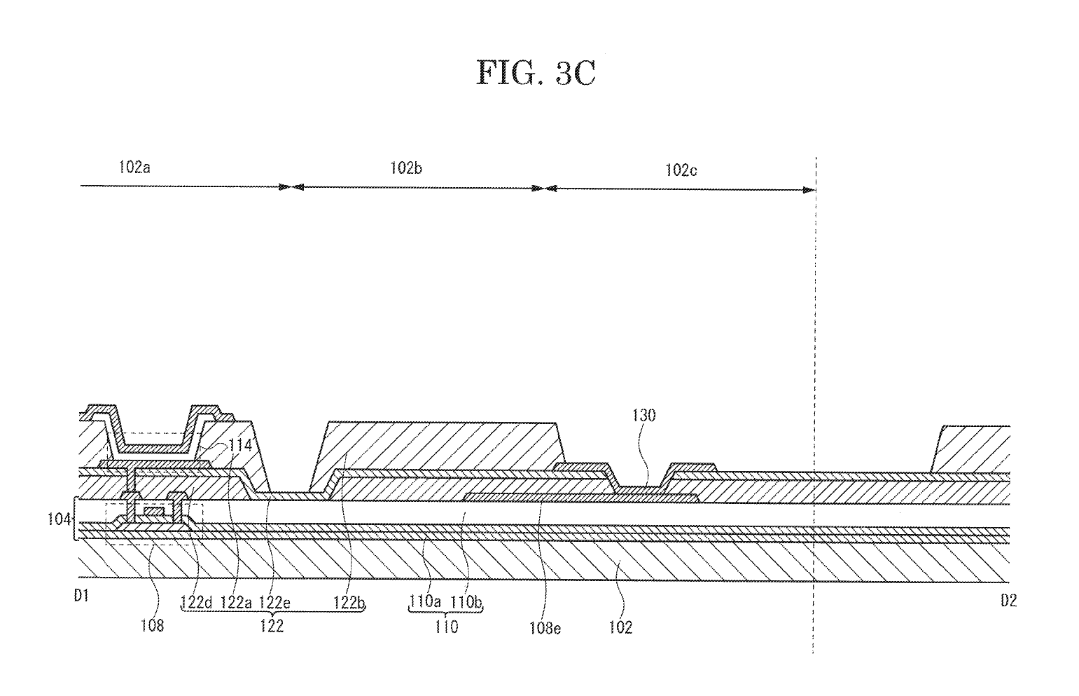

A method of forming a plurality of pixels 112, a partition layer 122 and a plurality of connection terminals 130 on the first surface of the substrate 102 is explained while referring to FIG. 3A, FIG. 3B, and FIG. 3C. Each of the plurality of pixels 112 includes a light emitting element 114. Here, the partition wall layer 122 includes a first partition wall 122a, a second partition wall 122b, a planarization insulating layer 122c and an inorganic insulating layer 122d. The first partition wall 122a is arranged at the periphery of each of the plurality of pixels 112, and the second partition wall 122b surrounds the first partition wall 122a. The connection terminal 130 is arranged on the outer side of the second partition wall 122b.

First, a planarization insulating layer 122c is formed above the circuit layer 104. The planarization insulating layer 122c is formed covering the source/drain electrode 108d and the terminal wiring 108e. The planarization insulating layer 122c has a function for absorbing unevenness and an inclination caused by the transistor 1089 and the terminal wiring 108e, and also provides a flat surface. An organic insulating material can be used as the material of the planarization insulating layer 122c. The organic insulating material can include polymer materials such as epoxy resin, acrylic resin, polyimide, polyamide, polyester, polycarbonate or poly-siloxane and the like. The planarization insulating layer 122c can be formed by a wet film formation method or the like.

Next, an inorganic insulating layer 122d is formed above the planarization insulating layer 122c. As described above, the inorganic insulating layer 122d not only functions as a protective layer with respect to the transistor 108 but also forms a capacitor with the first electrode 116 of the light emitting element 114 which is formed later. Therefore, it is preferred to use a material which has a relatively high dielectric constant. For example, it is possible to use silicon nitride, silicon nitride oxide or silicon oxynitride and the like. A CVD method or a sputtering method can be applied as a film formation method.

Next, the inorganic insulating layer 122d and the planarization insulating layer 122c are etched using the source/drain electrode 108d and the terminal wiring 108e as etching stoppers to form openings. Following this, the first electrode 116 and the connection terminal 130 are formed to cover these openings.

In the case when light emitted from the light emitting element 114 is extracted from the second electrode 120, the first electrode 116 is formed to reflect visible light. In this case, a metal which has high reflectivity such as silver or aluminum or an alloy thereof is used for the first electrode 116. Alternatively, a layer of a conductive oxide having translucency is formed over the layer containing these metals or alloys. ITO and IZO ae examples of the conductive oxide. In the case when light emitted from the light emitting element 114 is extracted from the first electrode 116, the first electrode 116 may be formed using ITO or IZO.

In the present embodiment, the first electrode 116 and a connection electrode are formed above the inorganic insulating layer 122d. Therefore, it is preferred to form a layer of the metal described above to cover the opening for example, and subsequently form a layer containing a conductive oxide which transmits visible light, and the it is possible to perform processing by etching in order to form the first electrode 116 and the connection electrode.

Next, a first partition wall 122a and a second partition wall 122b are formed. The first partition wall 122a absorbs steps caused by the end part of the first electrode 116 and electrically insulates the first electrode 116 of adjacent pixels 112 from each other.

In addition, when forming the first organic insulating layer 124b which forms the sealing layer 124 in a later manufacturing step, it is necessary that the first organic insulating layer 124b covers the display region 102a and is selectively formed in a region within the surface of the substrate 102 so as not to spread to the end part of the substrate 102. The first organic insulating layer 124b is selectively formed in the display region 102a using an inkjet method for example. At this time, the second partition wall 122b has a function of blocking the first organic insulating layer 124b so as not to spread outside the second partition wall 122b.

A material which can be used for the planarization insulating layer 122c such as an epoxy resin or an acrylic resin can be used for the first partition wall 122a and the second partition wall 122b and can be formed by a wet film formation method.

Next, the light emitting layer 118 and the second electrode 120 are formed to cover the first electrode 116 and the partition wall layer 122. The light emitting layer 118 mainly incudes an organic compound and can be formed by applying a wet film forming method such as an ink jet method or a spin coating method or a dry film forming method such as vapor deposition method.

In the case when the light emitted from the light emitting element 114 is extracted from the first electrode 116, a metal such as aluminum, magnesium, silver or an alloy of these may be used as the material of the second electrode 120. On the other hand, in the case when the light emitted from the light emitting element 114 is extracted from the second electrode 120, a conductive oxide having translucency such as ITO may be used as the material of the second electrode 120. Alternatively, the second electrode 120 can be formed with a thickness so that visible light can pass through the metals described above. In this case, a conductive oxide having translucency may be further stacked.

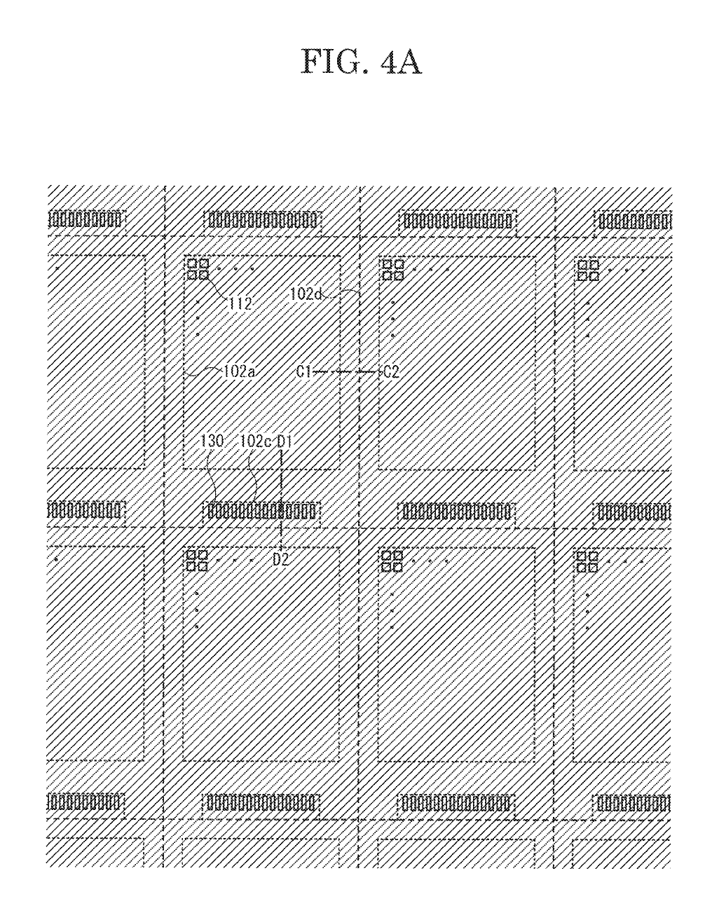

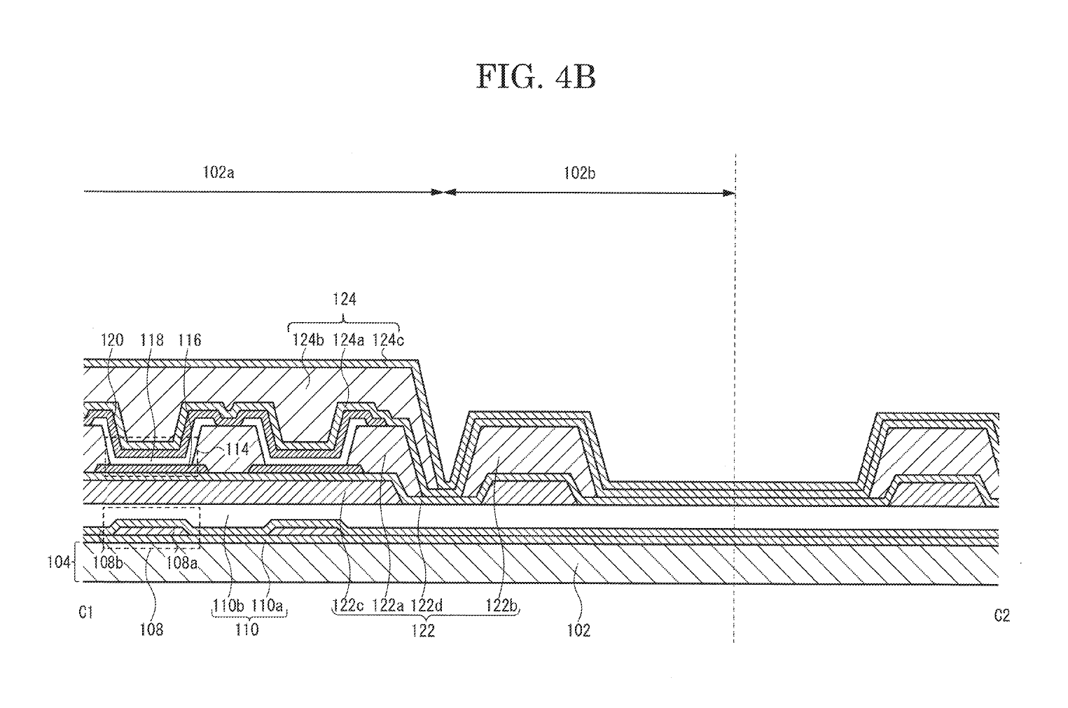

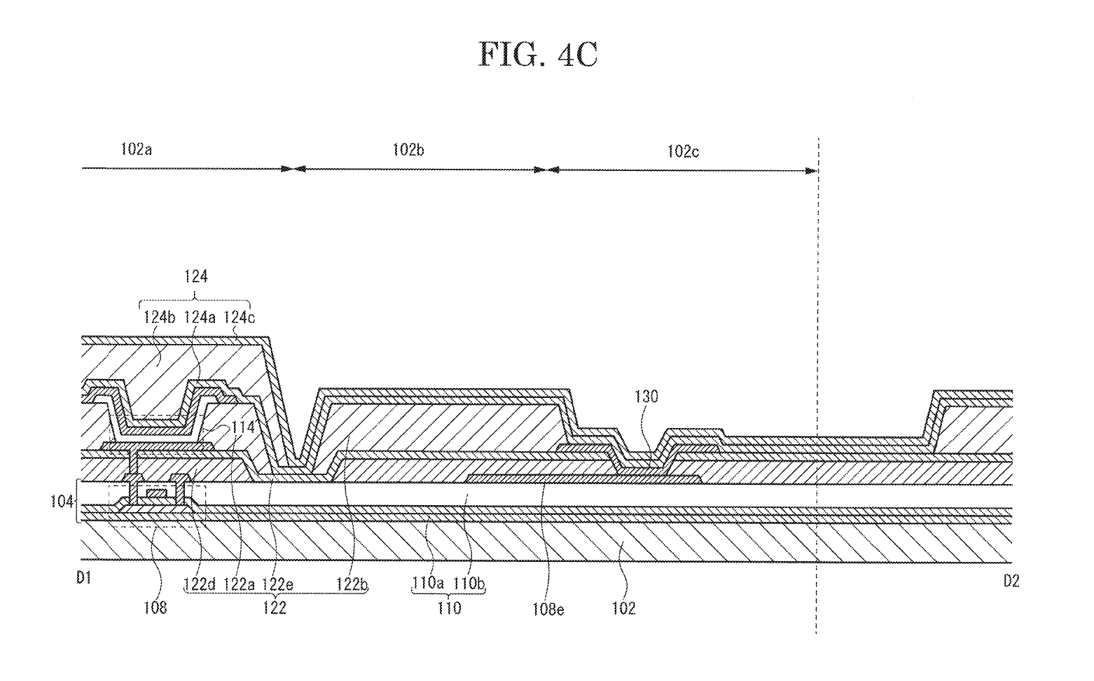

Next, a method of forming the sealing layer 124 is explained while referring to FIG. 4A, FIG. 4B, and FIG. 4C. Here, the sealing layer 124 includes a third inorganic insulating layer 124a, a first organic insulating layer 124b and a fourth inorganic insulating layer 124c. The third inorganic insulating layer 124a is formed across the surface of the substrate 102. The first organic insulating layer 124b covers the third inorganic insulating layer 124a and the plurality of pixels 112 and is arranged on the inner side of the second partition wall 122b. The fourth inorganic insulating layer 124c is arranged above and across the surface of the first organic insulating layer 124b.

First, the third inorganic insulating layer 124a is formed across the first surface of the substrate 102. The third inorganic insulating layer 124a can include an inorganic material such as silicon nitride, silicon oxide, silicon nitride oxide, silicon oxynitride or the like and can be formed using the same method as the insulating layer 110.

Next, the first organic insulating layer 124b is formed. The first organic insulating layer 124b is formed by coating on the inner side of the second partition wall 122b. The first organic insulating layer 124b may contain an organic resin including acrylic resin, poly-siloxane, polyimide and polyester or the like. In addition, the first organic insulating layer 124b may be formed so as to provide a flat surface in order to absorb unevenness caused by the partition wall layer 122. The organic insulating layer is preferred to be selectively formed in the display region 102a. That is, it is preferred that the organic insulating layer is formed to not overlap a connection electrode. The first organic insulating layer 124b can be formed by a wet film formation method such as an inkjet method. At this time, the first organic insulating layer 124b selectively coated in the display region 102a is blocked by the second partition wall 122b and does not spread to the outer side.

Next, a fourth inorganic insulating layer 124c is formed. The fourth inorganic insulating layer 124c has the same structure as the third inorganic insulating layer 124a and can be formed by the same method. The fourth inorganic insulating layer 124c can also be formed to cover not only the first organic insulating layer 124b but also a connection electrode. In this way, it is possible for the first organic insulating layer 124b to be sealed by the third inorganic insulating layer 124a and the fourth inorganic insulating layer 124c.

By the processes described so far, the sealing layer 124 has a three-layer structure including the third inorganic insulating layer 124a, the first organic insulating layer 124b and the fourth inorganic insulating layer 124c on the inner side of the second partition wall 122b. In addition, the sealing layer 124 has a two-layer structure including a third inorganic insulating layer 124a and a fourth inorganic insulating layer 124c on the outer side of the second partition wall 122b.

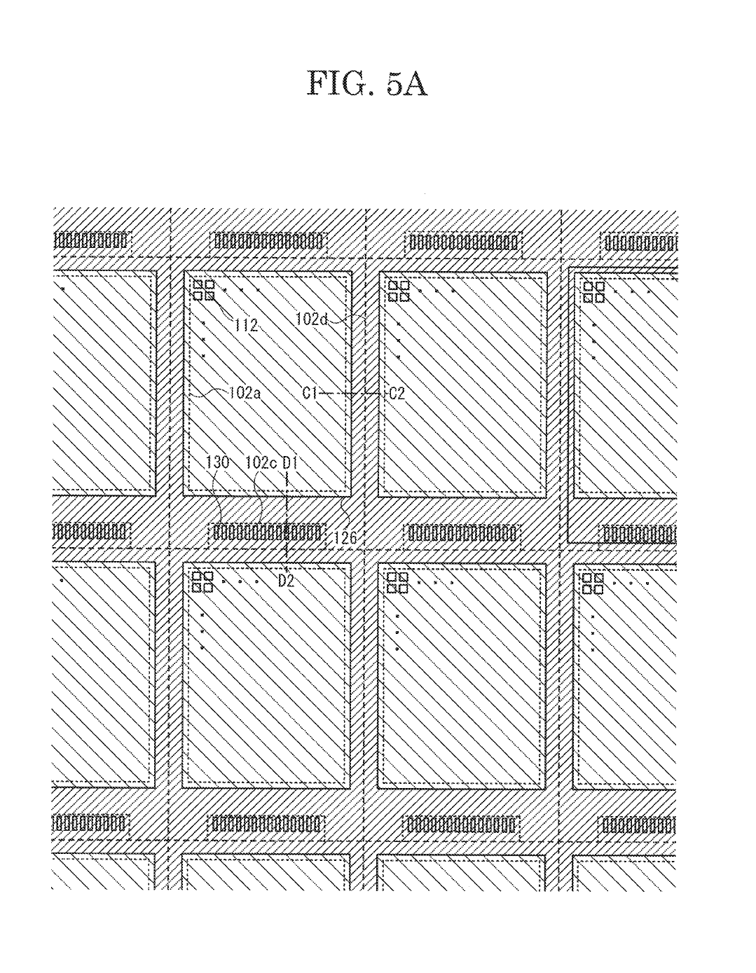

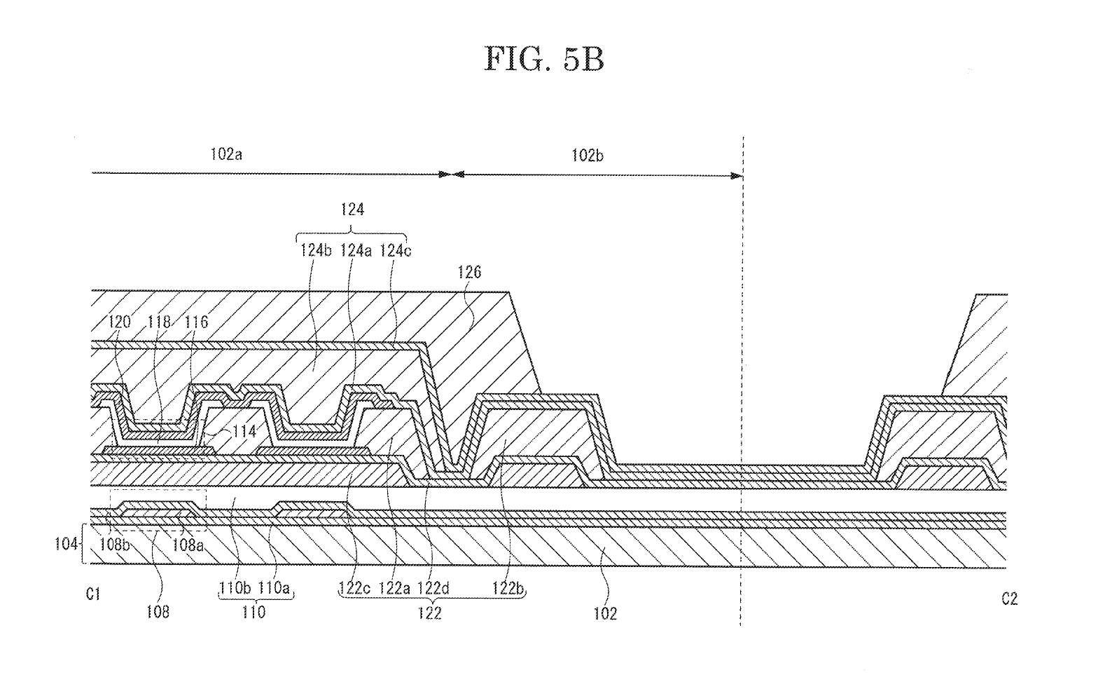

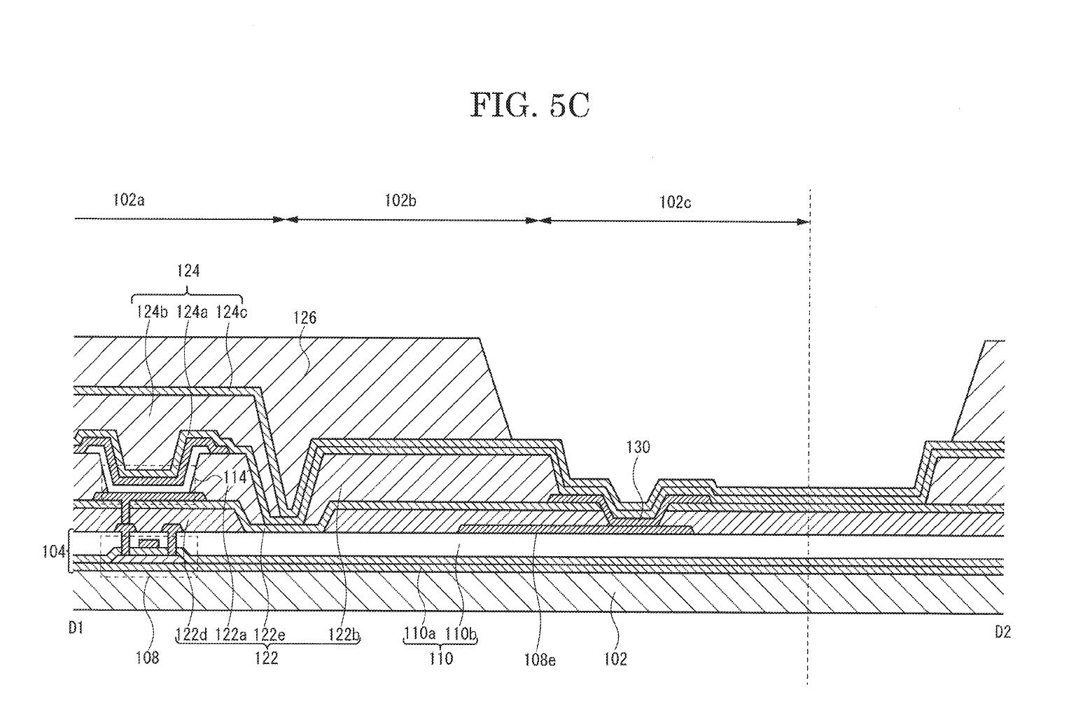

Next, a method of forming the protective layer 126 is explained while referring to FIG. 5A, FIG. 5B, and FIG. 5C. The protective layer 126 is arranged above the sealing layer 124. As is shown in FIG. 5A, FIG. 5B, and FIG. 5C, it is preferred that the protective layer 126 covers a region where the third inorganic insulating layer 124a and the fourth inorganic insulating layer 124c are in contact with each other selectively in the display region 102a and is formed to not overlap with a connection terminal 130. The protective layer 126 can include the same material as the first organic insulating layer 124b which forms the sealing layer 124 and can be formed using the same method as the first organic insulating layer 124b.

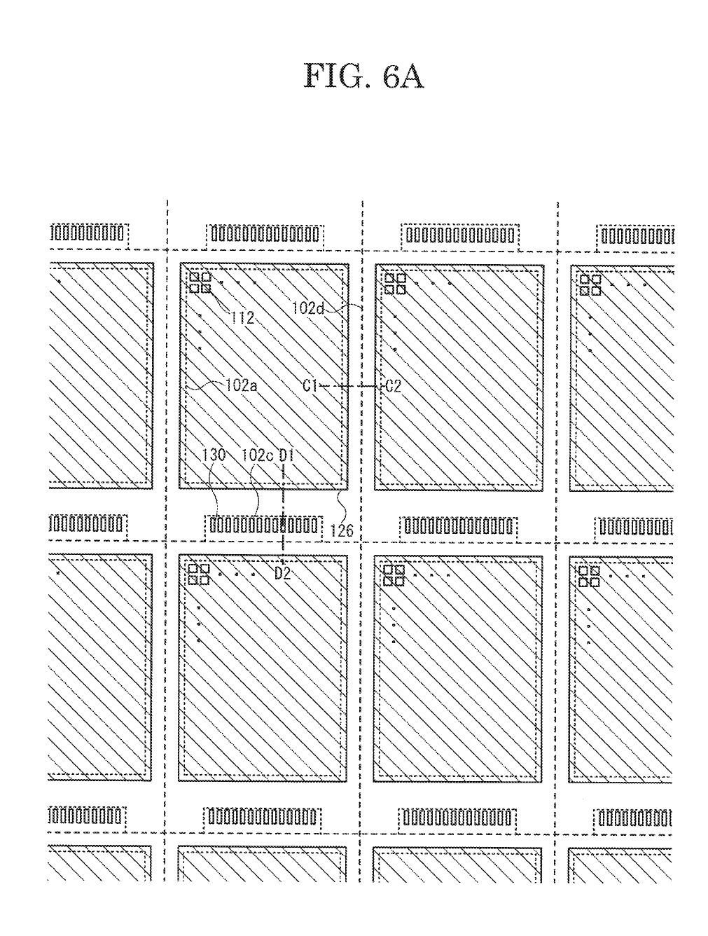

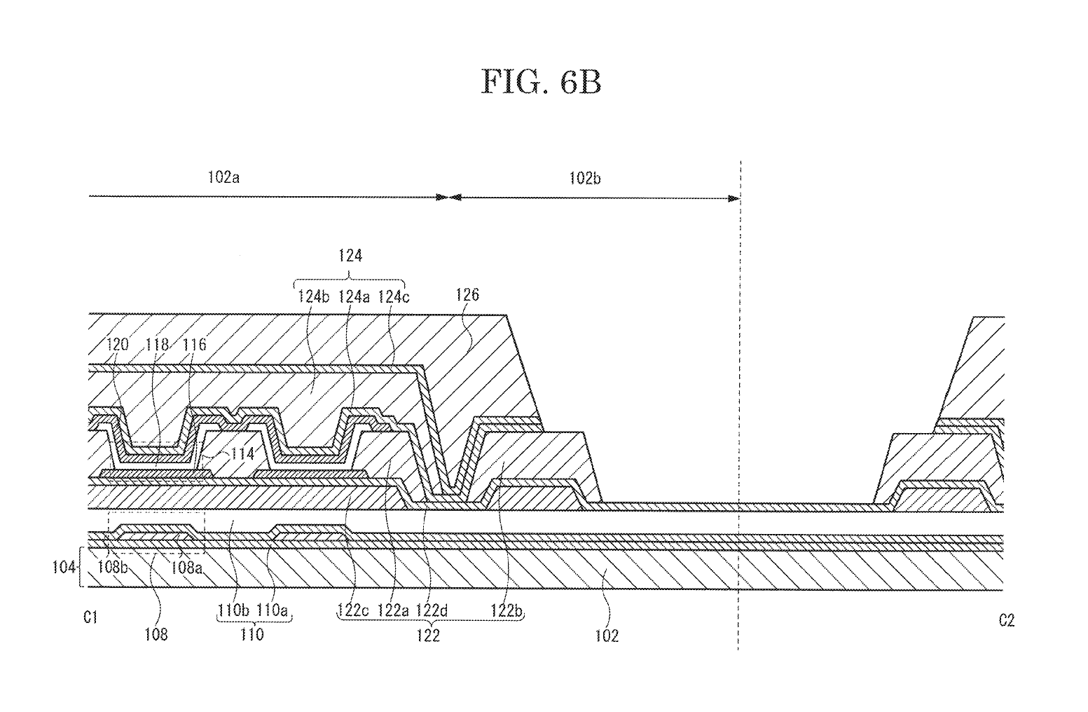

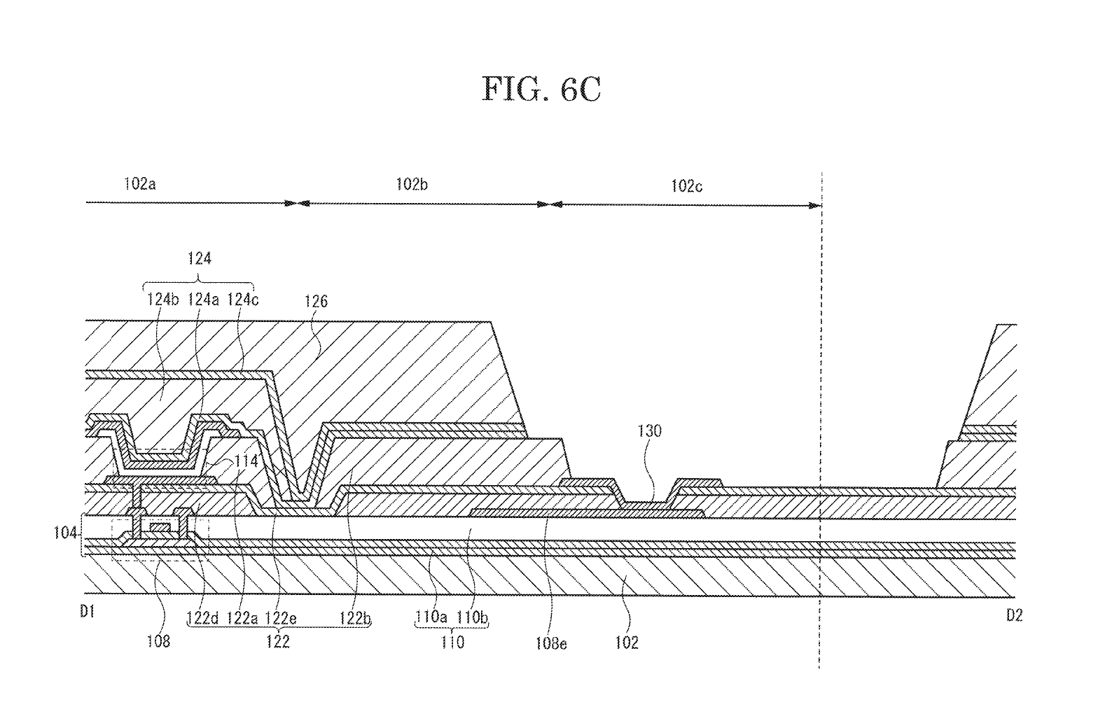

Next, a method of exposing the plurality of connection terminals 130 covered by the sealing layer 124 using the steps up to now is explained while referring to FIG. 6A, FIG. 6B, and FIG. 6C. Here, the sealing layer 124 is etched to expose the plurality of connection terminals 130 using the protective layer 126 as a mask. Here, the region of the sealing layer 124 exposed in the protective layer 126 is a region having a two-layer structure including the third inorganic insulating layer 124a and the fourth inorganic insulating layer 124c.

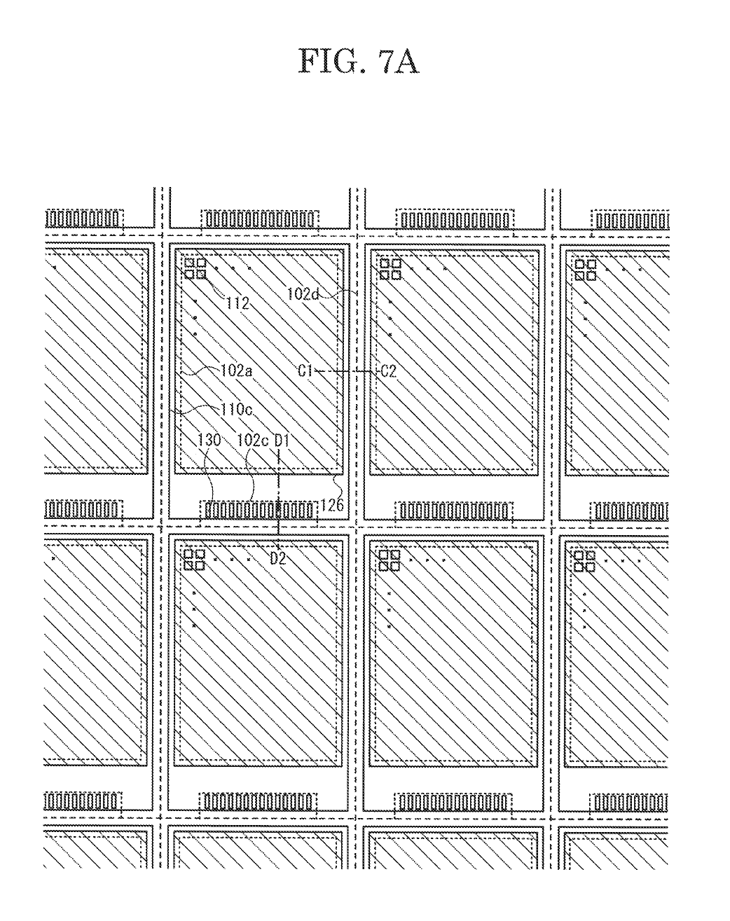

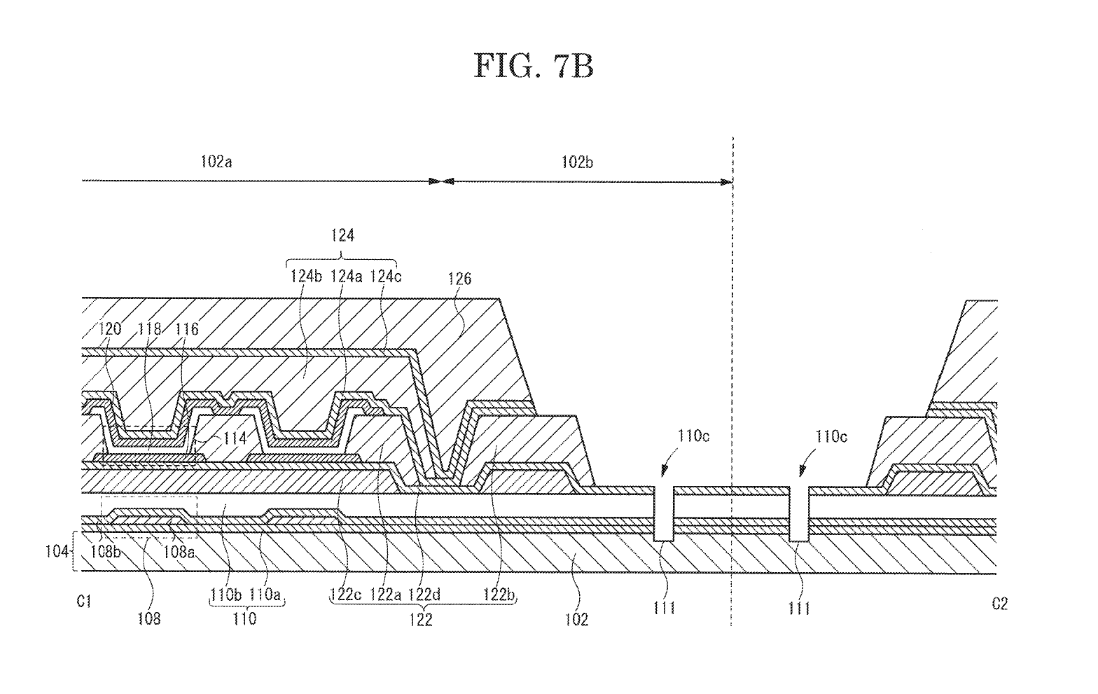

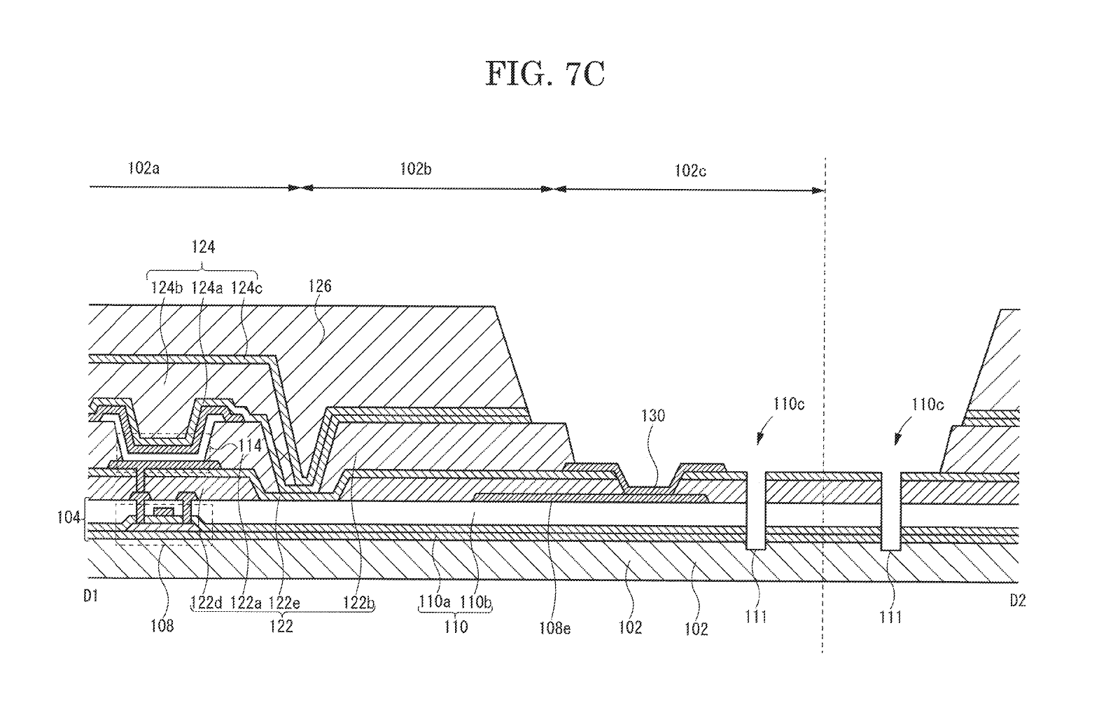

Next, a method of forming the through hole 110c is explained while referring to FIG. 7A, FIG. 7B, and FIG. 7C. The through hole 110c passes through at least the insulating layer 110 in each of a plurality of regions defined for forming the plurality of display devices 100 and is formed to surround the circuit 106 in a planar view. In the present embodiment, the through hole 110c is formed along the edge of the display device 100 in a frame shape surrounding the circuit 106.

The through hole 110c can be formed by energy irradiation. Laser irradiation can be used as the energy irradiation. A solid laser, a gas laser or a liquid laser or the like can be used as the type of laser. Preferably, a solid laser can be used and more preferably a YAG laser or the like can be used. It is particularly preferable to use a third harmonic as the YAG laser. Here, a part of the substrate 102 may be cut when the through hole 110c is formed. In the present embodiment, a bottom hole 111 is formed in a region of the substrate 102 which overlaps the through hole 110c.

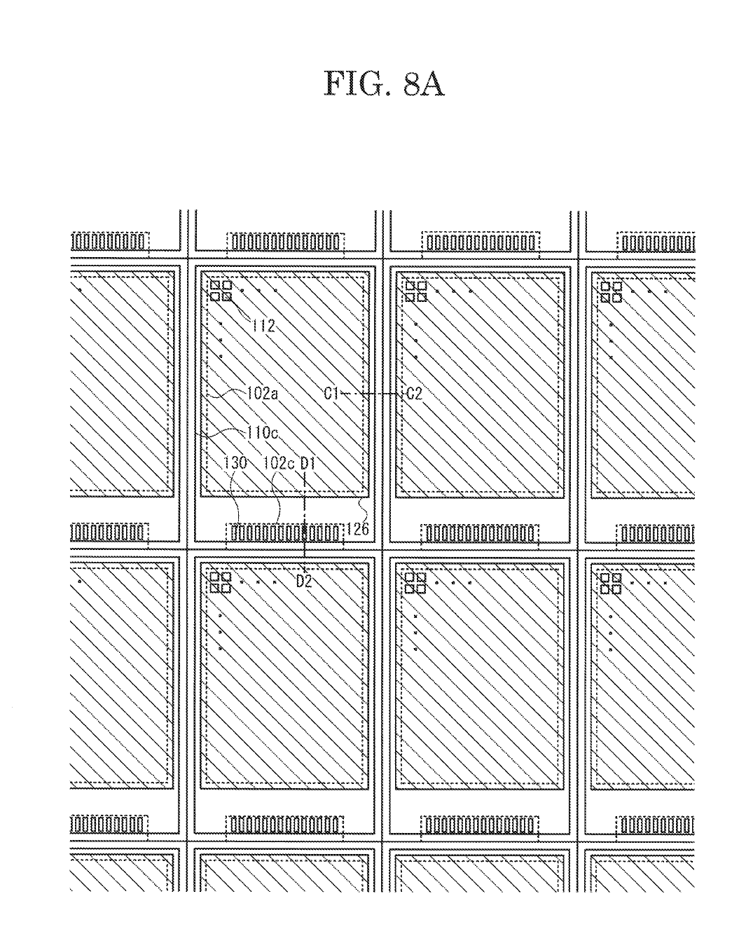

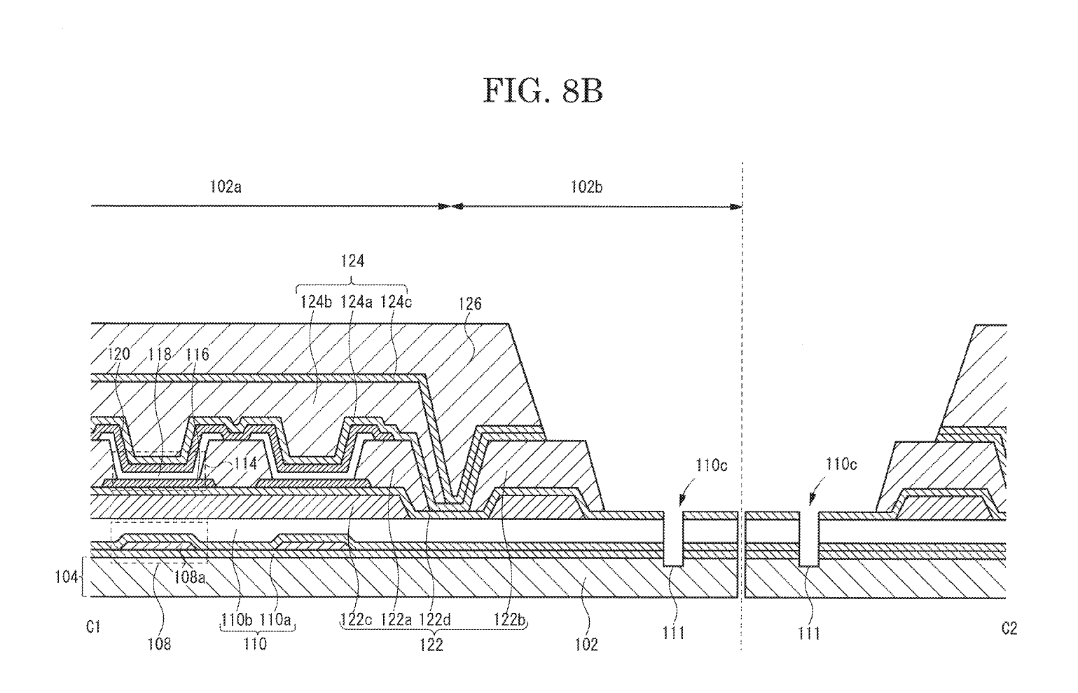

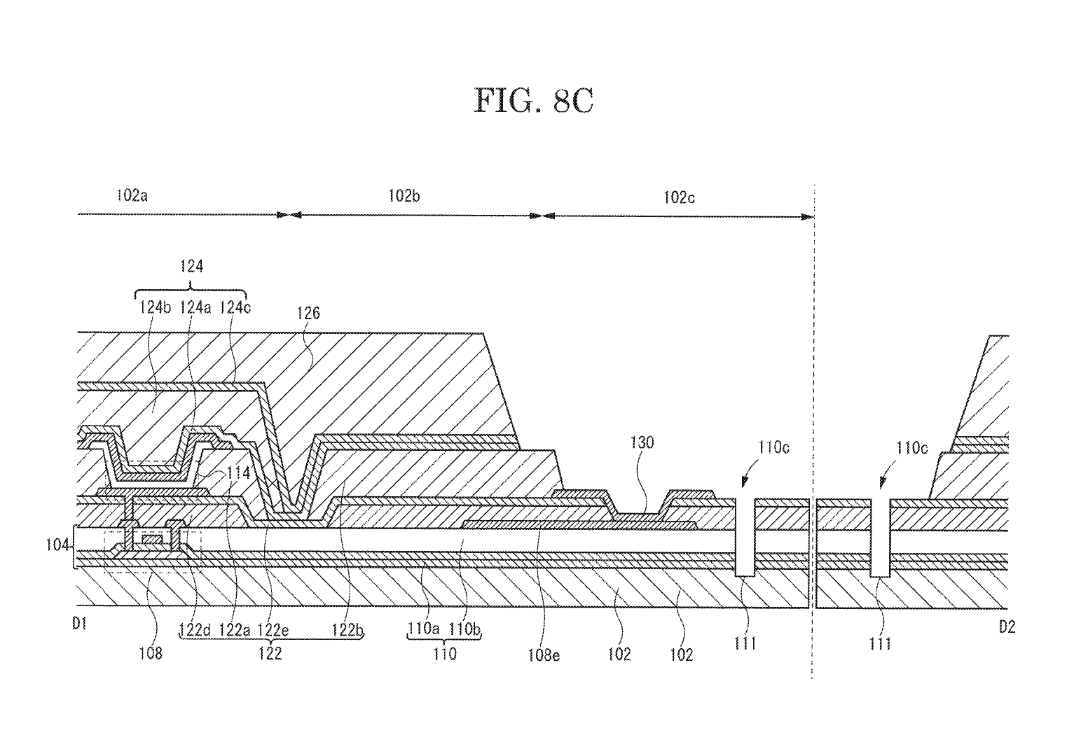

Next, a method of dividing the display device 100 into a plurality of display devices 100 is explained while referring to FIG. 8A, FIG. 8B, and FIG. 8C. The display device is divided into a plurality of display devices 100 along the division line 102d. Division of the substrate 102 can be performed using mechanical processing such as blade dicing or optical processing such as laser ablation.

Here, in the case when the substrate 102 is divided by mechanical processing such as blade dicing, defects such as cracks can easily occur in the insulating layer 110 containing an inorganic material for example near the division line 102d. As described above, when the defect grows and reaches the display region 102a, for example, there is concern that the circuit 106 may be broken due to such a defect. In addition, the defect may become a moisture entry path, and moisture which reaches the display region 102a from the exterior of the display device 100 may deteriorate the light emitting layer 118.

The display device 100 according to the present embodiment can prevent defects such as cracks occurring in the vicinity of an end part of the display device 100 from growing further inward from the through hole 110c by arranging the through hole 110c as described above. In this way, it is possible to prevent the circuit 106 from breaking and the light emitting element 114 from deteriorating due to moisture. In this way, the manufacturing yield and reliability of the display device 100 are improved.

Next, connectors such as the FPC substrate 138 are connected in the terminal region 102c using an anisotropic conductive film 136, whereby it is possible to form the display device 100 shown in FIG. 1A, FIG. 1B, and FIG. 1C.

In the manufacturing method of the display device 100 according to the present embodiment, a mode is shown in which the through hole 110c is formed after the sealing layer 124 is etched in order to expose the plurality of connection terminals 130 and before the substrate 102 is divided. However, the step of forming the through hole 110c is not limited to this. For example, the through hole 110c may be formed before the step of forming the sealing layer 124. In addition, although explained in other embodiments later, the through hole 110c may be formed after connecting the FPC substrate 138 and the like to the terminal region 102c.

According to the manufacturing method of the display device 100 according to the present embodiment, it is possible to prevent deterioration of the sealing layer 124 during the manufacturing process. In this way, it is possible to provide the display device 100 with improved manufacturing yield and reliability.

### Second Embodiment

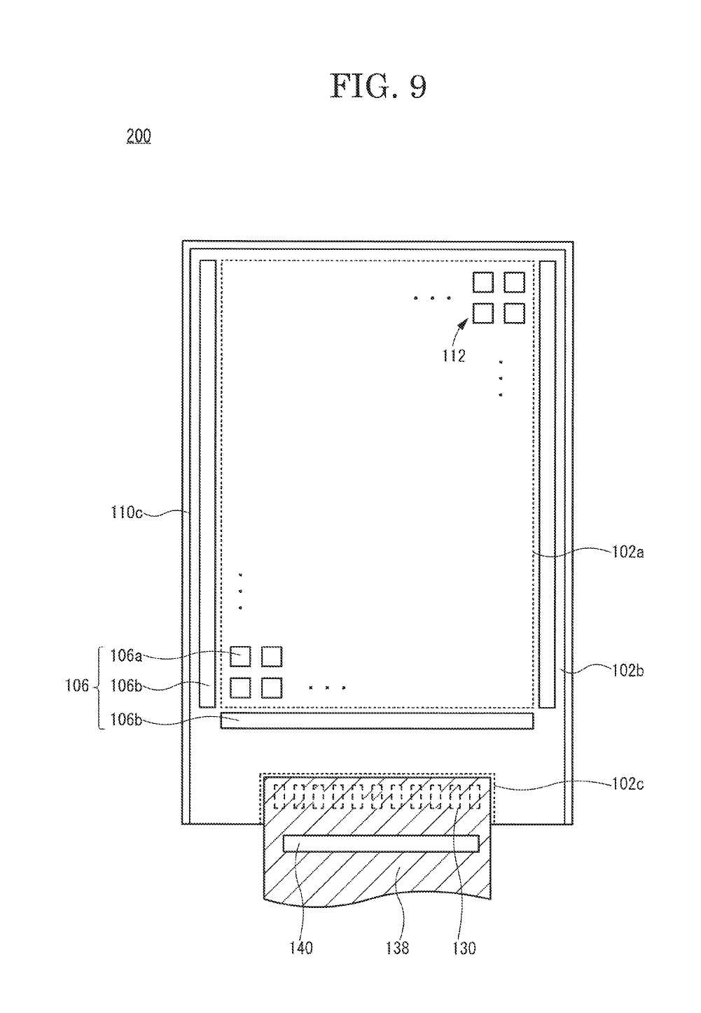

FIG. 9 is a top view diagram showing a structure of a display device 200 according to the present embodiment. The layout of the through hole 110c of the display device 200 is different from that of the display device 100 according to the first embodiment. In the present embodiment, the through hole 110c is arranged along three sides of the rectangular display device 200. In other words, the through hole 110c is not arranged on one side where the terminal region 102c is arranged.

In the explanation of the manufacturing method of the display device 100 according to the first embodiment, a mode was shown in which the FPC substrate 138 is connected to the terminal region 102c after forming the through hole 110c. As a result, in the display device 100, the through hole 110c can be arranged in a frame shape surrounding the pixel circuit 106a, the periphery circuit 106b, the plurality of connection terminals 130 and connection wiring.

On the other hand, as in the present embodiment, the through hole 110c may be formed after connecting the FPC substrate 138 to the terminal region 102c. When forming the through hole 110c, it is formed along only the three sides mentioned previously so as not to cut the connection wiring extending from the terminal region 102c.

In addition, the present invention is not limited to the mode in which the through hole 110c is formed along three sides of the display device 200 as in the present embodiment. For example, the FPC substrate 138 may be connected to the terminal region 102c, and the through hole 110c may be formed when a defect such as a crack is detected in the vicinity of an end part of the display device 200 during an inspection stage of the display device 200. That is, the through hole 110c may be formed around the defect. In this case, the through hole 110c may be formed in a frame shape in order to surround the defect. In addition, the end part of the display device 200 and the through hole 110c may be formed to surround the defect. In this way, it is possible to prevent cracks from growing from the detected defect as a starting point and entering the display region 102a.

### Third Embodiment

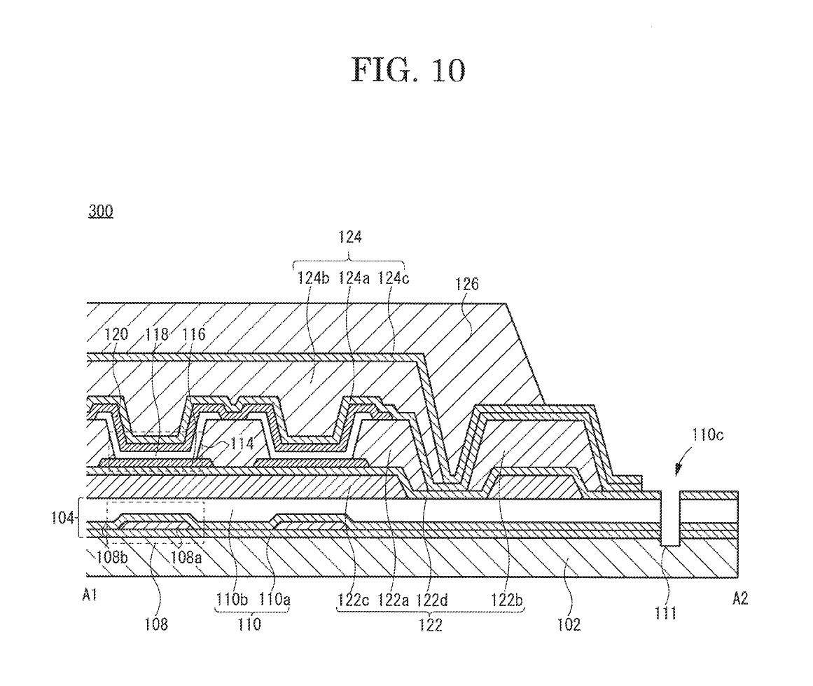

FIG. 10 is a cross-sectional diagram showing a structure of a display device 300 according to the present embodiment. The display device 300 differs from the display device 100 according to the first embodiment in the structure of the sealing layer 124. In the present embodiment, the end part of the sealing layer 124 is arranged on the inner side of the frame shaped through hole 110c. In this way, the through hole 110c passes through the inorganic insulating layer 122d, the second inorganic insulating layer 110b, the gate insulating layer 108b and the first inorganic insulating layer 110a. That is, the through hole 110c does not pass through the part where the fourth inorganic insulating layer 124c and the third inorganic insulating layer 124a of the sealing layer 124 are stacked. In this way, compared with the first embodiment, it is possible to suppress the intensity of the laser for forming the through hole 110c in the manufacturing process to a low level, and it is possible to suppress manufacturing costs.

### Fourth Embodiment

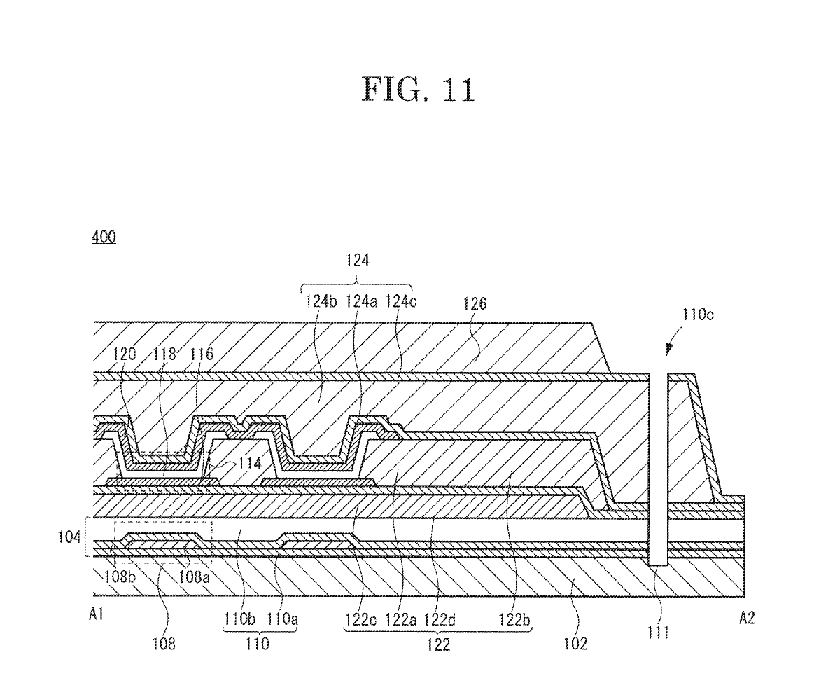

FIG. 11 is a cross-sectional diagram showing a structure of a display device 400 according to the present embodiment. The display device 400 is different from the display device 100 according to the first embodiment in the structure of the sealing layer 124. In the present embodiment, the end part of the first organic insulating layer 124b which forms the sealing layer 124 is arranged on the outer side of the through hole 110c. Along with this, the through hole 110c which is formed at the periphery of the display device 400 passes through d the fourth inorganic insulating layer 124c, the first organic insulating layer 124b, the third inorganic insulating layer 124a, the inorganic insulating layer 122d, the second inorganic insulating layer 110b, the gate insulating layer 108b and the first inorganic insulating layer 110a. In this way, in the manufacturing process, when forming the through hole 110c, the laser is irradiated in a state in which each layer lower from the inorganic insulating layer 122d is protected by the sealing layer 124. In this way, it is possible to suppress scattering and peeling of the inorganic material by laser irradiation in layers lower than the inorganic insulating layer 122d and which eventually cause defects in the insulating layer 110 of the circuit layer 104. In this way, it is possible to improve manufacturing yield and provide the display device 400 with improved reliability.

### Fifth Embodiment

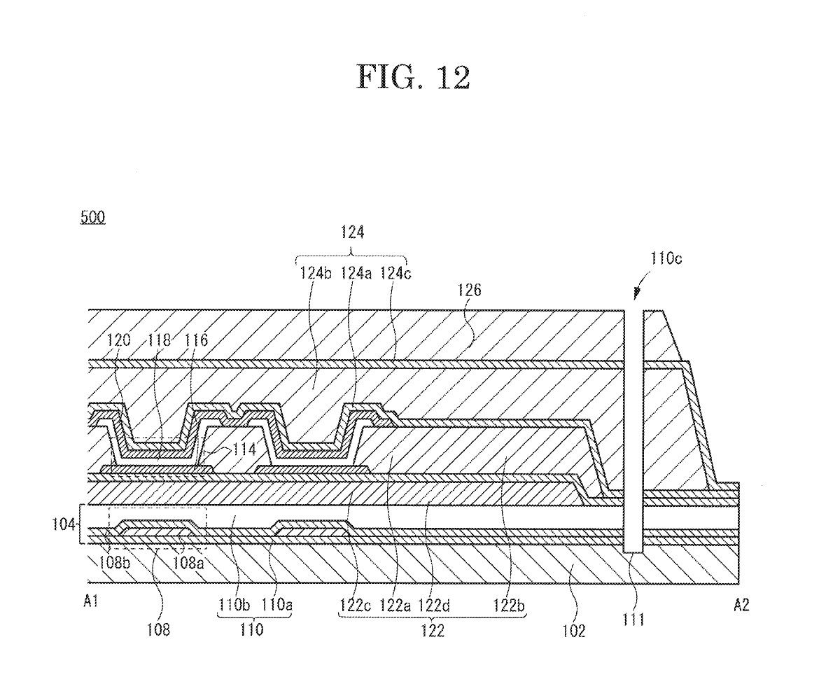

FIG. 12 is a cross-sectional diagram showing a structure of a display device 500 according to the present embodiment. The display device 500 differs from the display device 400 according to the fourth embodiment in the structure of the protective layer 126. In the present embodiment, the protective layer 126 is arranged on the outer side of the frame shaped through hole 110c. Along with this, the through hole 110c which is formed at the periphery of the display device 500 further passes through the protective layer 126 in addition to the fourth inorganic insulating layer 124c, the first organic insulating layer 124b, the third inorganic insulating layer 124a, the inorganic insulating layer 122d, the second inorganic insulating layer 110b, the gate insulating layer 108b and the first inorganic insulating layer 110a. In this way, similar to the fourth embodiment, when forming the through hole 110c in the manufacturing process, the laser is irradiated in a state in which layers lower than the inorganic insulating layer 122d are protected by the sealing layer 124. In this way, occurrence of peeling which is a concern due to scattering of the inorganic material or laser irradiation can be suppressed in layers lower than the inorganic insulating layer 122d which causes defects in the insulating layer 110 of the circuit layer 104. Further, the laser is irradiated in a state where the fourth inorganic insulating layer 124c is protected by the protective layer 126. In this way, it is possible to suppress scattering of the inorganic material of the fourth inorganic insulating layer 124c during laser irradiation and it is possible to suppress the occurrence of defects in the circuit layer 104 as a starting point. In this way, it is possible to improve manufacturing yield and provide the display device 500 with improved reliability.

Each embodiment described above as embodiments of the present invention can be implemented in combination as appropriate as long as they do not contradict each other. In addition, a person skilled in the art can appropriately add, delete or change the design of constituent elements based on the display device of each embodiment or those in which processes are added, omitted or conditions are changed as long as it includes the concept and is included within the scope of the present invention.

In the present specification, although the case of an EL display device has been mainly exemplified as a disclosed example, as another application example, an electronic paper type display having other self-light emitting type display devices, liquid crystal display devices, electrophoretic elements or the like and flat panel display devices such as display devices may be exemplified. In addition, the present invention can be applied from medium to small size to large size applications without any particular limitation.

Even if other actions and effects different from the actions and effects brought about by the modes of each embodiment described above are obvious from the description of the present specification or are easily predictable by a person skilled in the art, such actions and effects are to be interpreted as being provided by the present invention.

What is claimed is:

1. A display device comprising:
a substrate;
a circuit layer arranged on a first surface of the substrate and including a transistor, wiring and an insulating layer; and
a plurality of pixels arranged over the circuit layer,
wherein
a display region where the plurality of pixels is located and a periphery region surrounding the display region are located above the first surface of the substrate;
the circuit layer is located across the display region and the periphery region; and
a through hole passing through the circuit layer is located in the periphery region of the circuit layer.

2. The display device according to claim 1, wherein the through hole is a frame shape surrounding the display region.

3. The display device according to claim 1, wherein the substrate includes a concave part in a region overlapping the through hole on the first surface.

4. The display device according to claim 1, wherein the transistor includes a semiconductor layer, and the insulating a layer includes a first inorganic insulating layer arranged on a lower layer of the semiconductor layer and a second inorganic insulating layer arranged on an upper layer of the semiconductor layer.

5. The display device according to claim 1, further comprising a plurality of light emitting elements included in each of the plurality of pixels, and a sealing layer covering the plurality of light emitting elements,
wherein the through hole also passes through the sealing layer.

6. The display device according to claim 5,
wherein the sealing layer includes a third inorganic insulating layer, a first organic insulating layer and a fourth inorganic insulating layer,
wherein an end part of the third inorganic insulating layer is arranged on the outer side of the through hole,
wherein the first organic insulating layer is arranged over the third inorganic insulating layer and overlaps the plurality of pixels, and
wherein the fourth inorganic insulating layer is arranged over the first organic insulating layer and an end part of the fourth inorganic insulating layer is arranged on the outer side of the though hole.

7. The display device according to claim 6, wherein an end part of the first organic insulating layer is arranged on an inner side of the through hole.

8. The display device according to claim 6, wherein an end part of the first organic insulating layer is arranged on an outer side of the through hole.

9. The display device according to claim 5, further comprising a protective layer is arranged over the sealing layer,
wherein the through hole also passes through the protective layer.

10. The display device according to claim 1, wherein the circuit layer includes a pixel circuit arranged in each of the plurality of pixels and controls light emission of each of the plurality of pixels, and a periphery circuit arranged in the periphery region and connected with the pixel circuit.

11. The display device according to claim 1, wherein the substrate includes a first side and a second side intersecting the first side, a plurality of terminals is located along the first side above the substrate, and the through hole extends along the second side and also intersects the first side.

12. The display device according to claim 11, wherein the substrate includes a third side facing the first side, and a fourth side facing the second side and intersecting the first side, and the through hole extends continuously along the second side, the third side and the fourth side.
